(19) United States
(12) Patent Application Publication
(10) Pub. No.: US 2016/0035979 A1
(43) Pub. Date: Feb. 4, 2016

(54) INVERSE-STRUCTURE ORGANIC LIGHT EMITTING DIODE AND MANUFACTURING METHOD THEREFOR

(71) Applicant: POSTECH ACADEMY - INDUSTRY FOUNDATION, Pohang-si (KR)

(72) Inventors: Tae-Woo LEE, Pohang-si (KR); Young-Hoon KIM, Daejeon (KR)

(21) Appl. No.: 14/880,096

(22) Filed: Oct. 9, 2015

Related U.S. Application Data
(63) Continuation of application No. PCT/KR2014/003127, filed on Apr. 10, 2014.

(30) Foreign Application Priority Data
Apr. 10, 2013 (KR) 10-2013-0039433
Mar. 21, 2014 (KR) 10-2014-0033715

(51) Int. Cl. H01L 51/00

(52) U.S. Cl. CPC H01L 51/004; H01L 2251/5353; H01L 2251/558; H01L 51/5092

(57) ABSTRACT

An organic light emitting diode comprises: a first electrode; an electronic injection layer disposed on the first electrode and containing a metallic oxide; an electronic injection interface layer disposed on the electronic injection layer and including a polymer containing a nitrogen atom; a light emitting layer disposed on the electronic injection interface layer; and a second electrode disposed on the light emitting layer. Accordingly, the electronic injection interface layer is formed between the electronic injection layer and the light emitting layer, so that an element efficiency can be improved, and as the thickness of the electronic injection interface layer becomes thicker, the work function of the electronic injection layer below the electronic injection interface layer increases, and an efficiency of injection of an electron to the light emitting layer is lowered.

### TECHNICAL FIELD

The present invention relates to an organic light emitting diode and a manufacturing method therefor, and, more specifically, to an inverse-structure organic light emitting diode and a manufacturing method therefor.

### BACKGROUND ART

Generally, organic light emitting diodes are devices which depend on electric semiconducting properties related to the HOMO (highest occupied molecular orbital) level and LUMO (lowest unoccupied molecular orbital) level of organic material, and each of them may include, in order, an anode, a light emitting layer and a cathode disposed on a substrate. In this case, it is common to use a transparent conductive oxide such as an indium tin oxide (ITO) as the anode.

In contrast, an inverse-structure organic light emitting diode includes, in order, a cathode, a light emitting layer and an anode, which are disposed on a substrate, and, in this case, a transparent conductive oxide such as an indium tin oxide (ITO) is used as the cathode. Ag or Au is used as the anode in this case. However, the electron injection barrier present in the direction from the cathode to the light emitting layer is large, and the excitons formed in the light emitting layer diffuse towards the cathode; therefore, a disadvantage of the operation efficiency such as luminance efficiency not being high exists.

### DISCLOSURE

### Technical Problem

Hence, the present invention was conceived for the purpose of solving the above-described problems, in consideration of providing a method for manufacturing an inverse-structure organic light emitting diode being stable in air and having an improved efficiency by applying an electron injection interface layer which is stable in air.

### Technical Solution

One aspect of the present invention provides an organic light emitting diode. Such an organic light emitting diode includes a first electrode, an electron injection layer disposed on the first electrode, an electron injection interface layer, which has a polymer containing a nitrogen atom, disposed on the electron injection layer, a light emitting layer disposed on the electron injection interface layer, and a second layer disposed on the light emitting layer.

Polymers of the above-described electron injection interface layer may be a dielectric polymer, and the above-described polymer may contain an amine group, an azo group or an ammonium group in its main or side chain. The above-described polymer may be a polyethylenimine-based polymer or a polyallylamine-based polymer. In addition, the above-described polymer may contain at least one selected from the group consisting of branched polyethyleneimine, polyethyleneimine ethoxylated, poly(2-ethyl-2-oxazoline), linear polyethyleneimine, bioreducible disulfide-crosslinked polyethyleneimine, polyethyleneimine max, polyallylamine, polyallylamine hydrochloride, poly(1-(4-(3-carboxy-4hydroxyphenylazo)benzenesulfonamido)-1,2-ethanediyl, sodium salt) and poly(diallyldimethylammonium chloride).

The thickness of the above-described electron injection interface layer is preferably 1 nm to 20 nm, and, with such thickness of the electron injection interface layer, it is possible to control the work function of the electron injection layer disposed below and the blocking of exciton dissociation (exciton separation) which takes place at the surface of an electron injection layer.

The above-described electron injection layer may be a thin film layer of a metal oxide, a layer of metal-oxide nanoparticles, or a layer in which metal-oxide nanoparticles are embedded in a metal-oxide thin film. The above-described metal oxide may be an n-type semiconducting metal oxide. Also, the metal oxide may be one or more type selected from the group consisting of a TiOₓ (where x is a real number of 1 to 3), indium oxide (In₂O₃), tin oxide (SnO₂), zinc oxide (ZnO), zinc tin oxide, gallium oxide (Ga₂O₃), tungsten oxide (WO₃), aluminum oxide, titanium oxide, vanadium oxide, molybdenum oxide, copper(II) oxide (CuO), nickel oxide (NiO), CopperAluminumOxide (CAO, CuAlO₂), ZincRhodiumOxide (ZRO, ZnRh₂O₄), iron oxide, chromium oxide, bismuth oxide, IGZO (indium-Gallium Zinc Oxide) and ZrO₂. In addition, between the above-described second electrode and the above-described light emitting layer, a hole injection layer containing a metal oxide may be disposed.

Also provided is an organic light emitting diode of another aspect of the present invention. Such an organic light emitting diode includes a first electrode, an electron injection layer disposed on the first electrode, an electron injection interface layer, which contains a polymer capable of forming an interface dipole by bonding with the oxygen of the above-mentioned metal oxide, disposed on the electron injection layer, a light emitting layer disposed on the electron injection interface layer, and a second layer disposed on the light emitting layer.

Still another aspect of the present invention provides a method for manufacturing an organic light emitting diode. The above-described manufacturing method includes a process of forming a first electrode, a process of forming, on the first electrode, an electron injection layer which contains a metal oxide, a process of forming, on the electron injection layer, an electron injection interface layer which contains a polymer having a nitrogen atom, a process of forming a light emitting layer on the electron injection interface layer, and a process of forming a second electrode on the light emitting layer.

The above-described electron injection interface layer may be formed by applying, on the above-described electron injection layer, a liquid mixture containing the above-described polymer and a polar solvent, and the polymer may be a dielectric polymer. In addition, the polymer may contain an amine group, an azo group or an ammonium group in its main or side chain, and the polymer may be a polyethyleneimine-based polymer or a polyallylamine-based polymer, and the polymer may contain at least one selected from the group consisting of branched polyethyleneimine, polyethyleneimine ethoxylated, poly(2-ethyl-2-oxazoline), linear polyethyleneimine, bioreducible disulfide-crosslinked polyethyleneimine, polyethyleneimine max), polyallylamine, polyallylamine hydrochloride, poly(1-(4-(3-carboxy-4hydroxyphenylazo)benzenesulfonamido)-1,2-ethanediyl, sodium salt) and poly(diallyldimethylammonium chloride).

The thickness of the above-described electron injection interface layer is formed preferably at 1 nm to 20 nm, and the electron injection layer may be a thin film layer of a metal oxide, a layer of metal-oxide nanoparticles, or a layer in which metal-oxide nanoparticles are embedded in a metal-oxide thin film. In addition, the metal oxide may be an n-type semiconducting metal oxide, and the electron injection interface layer may be formed through a sol-gel method or a deposition method.

### Advantageous Effects

According to the present invention, an organic light emitting diode exhibiting stability in air in every layer and improved efficiency can be produced through the formation, between an electron injection layer and a light emitting layer, of an electron injection interface layer capable of forming an interface dipole, and the electron injection and exciton dissociation of the device can be controlled through the thickness of the electron injection interface layer.

### DESCRIPTION OF DRAWINGS

FIGS. 1a to 1c are cross-sectional views showing a method for manufacturing an inverse-structure organic device according to one embodiment of the present invention.

FIG. 2 is a cross-sectional view showing an enlarged interface between an electron injection layer and an electron injection interface layer.

FIG. 3 is graphs showing changes in the work functions of electron injection layers prepared according to Manufacturing Examples 1 to 8 and Comparative Example.

FIG. 4a is a graph showing the measured lifetime of excitons when a light emitting layer is deposited during the manufacture of organic light emitting devices according to Manufacturing Example 2, Manufacturing Example 6 and Comparative Example.

FIG. 4b is a photoluminescence graph showing the measured intensity of excitons when a light emitting layer is deposited according to Manufacturing Example 1, Manufacturing Example 2, Manufacturing Example 3, Manufacturing Example 4 and Comparative Example

### EMBODIMENTS

Hereinafter, in order to illustrate the present invention more specifically, embodiments of the present invention will be described in detail with reference to the accompanying drawings. However, the present invention should not be limited to the embodiments set forth herein but may be embodied in different forms. Like reference numerals throughout the specification represent like elements.

In the case where a layer is stated to be “on” the other layer or a substrate in the present specification, it may be formed directly on the other layer or on the substrate, but there may be a third layer interposed therebetween. In addition, directional expressions in the present specification, such as above, on (top of), on the surface, etc., may be interpreted to have such meanings as under, below, below the surface, etc., depending on the reference. In other words, the representation of the spatial orientation should be understood in a relative sense and not to be interpreted to mean the absolute direction.

In the drawings, the thicknesses of layers and regions may be exaggerated or omitted for clarity.

### Organic Light Emitting Device

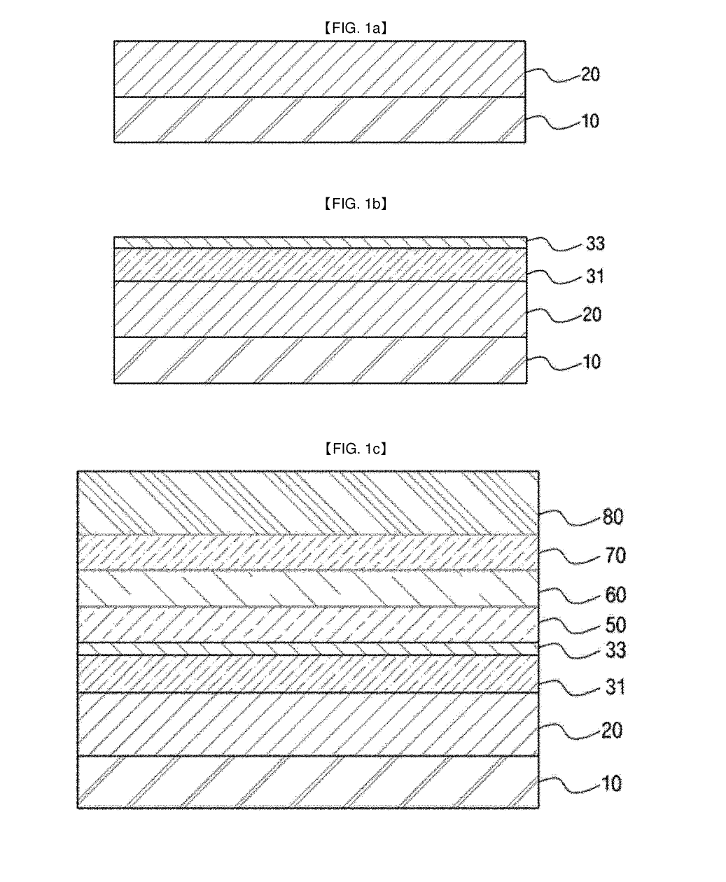

FIGS. 1a to 1c are cross-sectional views showing a method for manufacturing an inverse-structure organic device according to one embodiment of the present invention.

Referring to FIG. 1a, the first electrode 20 is formed on top of the substrate 10.

The substrate 10 may be a light-transmitting substrate or a light-reflecting substrate. The substrate 10 may include glass, sapphire, a silicon oxide, a metal foil (for example, a metal foil containing one or more metal selected among copper, aluminum, gold, platinum, palladium, silver, nickel, lead, neodymium, zinc and tin), a steel substrate (for example, a foil substrate consisting of one or more material selected among steel, carbon steel, special steel, stainless steel, cast iron and steel casting), a metal oxide, a polymer substrate and a combination of two or more thereof. Examples of the metal oxide include aluminum oxide, molybdenum oxide, indium oxide, tin oxide and indium tin oxide, and examples of the polymer substrate include, but are not limited to, a kapton foil, polyethersulfone (PES), polyacrylate (PAR), polyetherimide (PEI), polyethylene napthalate (PEN), polyethyleneterepthalate (PET), polyphenylene sulfide (PPS), polyallylate, polyimide, polycarbonate (PC), cellulose triacetate (TAC), cellulose acetate propinonate (CAP), etc.

The first electrode 20 may be a cathode. In addition, the first electrode 20 may be a reflective type electrode or a light-transmitting type electrode. In the case where the first electrode 20 is a light-transmitting type, it may be formed by using at least one among a transparent and highly conductive FTO (Fluorine-doped Tin Oxide), indium tin oxide (ITO), indium zinc oxide (IZO), tin oxide (SnO₂), zinc oxide (ZnO), graphene, a carbon thin film and a carbon nanotube. Or, on the other hand, in the case where the first electrode 20 is a reflective type electrode, it may be formed by using at least one among magnesium (Mg), aluminum (Al), aluminum-lithium (Al—Li), calcium (Ca), magnesium-indium (Mg—In) and magnesium-silver (Mg—Ag). The first electrode 20 may include two materials different from each other. In addition, various modifications such as to form the first electrode 20 into a structure of two layers, each of which includes one of the two materials different from each other, are possible. The first electrode 20 may have a thickness of 1 to 500 nm.

In addition, the substrate 10 and the first electrode 20 may be formed integrally. As an example, the substrate 10 and the first electrode 20 may be formed integrally by using a metal foil.

The first electrode 20 may be formed by using a vacuum deposition method, a sputtering method, a vapor deposition method or an ion-beam deposition method.

Referring to FIG. 1b, the electron injection layer 31 is formed on top of the first electrode 20.

The electron injection layer 31 may contain a metal oxide. The metal oxide has n-type semiconducting properties, thus having an excellent electron transporting ability, and further, it may be selected from semiconductor materials which have no reactivity towards air or moisture and excellent transparency in the range of visible light.

The electron injection layer 31 may contain at least one metal oxide selected among, for example, TiOₓ (where x is a real number of 1 to 3), indium oxide (In₂O₃), tin oxide (SnO₂), zinc oxide (ZnO), zinc tin oxide, gallium oxide (Ga₂O₃), tungsten oxide (WO₃), aluminum oxide, titanium oxide, vanadium oxide (V₂O₅, vanadium(IV) oxide(VO₂), V₄O₇, V₅O₉ or V₂O₃), a molybdenum oxide (MoO₃ or MoOₓ), copper(II) oxide (CuO), nickel oxide (NiO), CopperAluminumOxide (CAO, CuAlO₂), ZincRhodiumOxide (ZRO, ZnRh₂O₄), iron oxide, chromium oxide, bismuth oxide, IGZO (indium-Gallium Zinc Oxide) and ZrO₂, but it is not limited thereto. As an example, the electron injection layer 31 may be a thin film layer of a metal oxide, a layer of metal-oxide nanoparticles, or a layer in which metal-oxide nanoparticles are embedded in a metal-oxide thin film.

The electron injection layer 31 may be formed by using a wet process or a deposition method.

In the case where the electron injection layer 31 is formed by a solution method (e.g. a sol-gel method) as an example of a wet process, the electron injection layer 31 can be formed by applying a liquid mixture for the electron injection layer, which includes at least one among a sol-gel precursor of a metal oxide and a nanoparticle metal oxide along with a solvent, on the substrate 10, and then heat-treating it. In this case, the solvent may be removed, or the electron injection layer 31 may be crystallized, by the heat treatment. The method for providing the above-described mixture for the electron injection layer on the first electrode 20 may be selected among, for example, a spin coating method, a casting method, a Langmuir-Blodgett (LB) method, a spray coating method, a dip coating method, a gravure coating method, a reverse offset coating method, a screen printing method, a slot-die coating method, a nozzle printing method and a dry transfer printing method, but it is not limited thereto.

The sol-gel precursor of the above-described metal oxide may contain at least one selected from the group consisting of metal salts (for example, metal halides, metal sulfate salts, metal nitrate salts, metal perchlorate salts, metal acetate salts, metal carbonate salts, etc.), metal-salt hydrates, metal hydroxides, metal alkyls, metal alkoxides, metal carbides, metal acetylacetonates, metal acids, metal acid salts, metal-acid hydrates, metal sulfides, metal acetates, metal alkanoates, metal phthalocyanines, metal nitrides and metal carbonates.

In the case where the metal oxide is ZnO, at least one selected from the group consisting of zinc sulfate, zinc fluoride, zinc chloride, zinc bromide, zinc iodide, zinc perchlorate, zinc hydroxide (Zn(OH)₂), zinc acetate (Zn(CH₃COO)₂), zinc acetate hydrates (Zn(CH₃(COO)₂.nH₂O), diethyl zinc (Zn(CH₃CH₂)₂), zinc nitrate (Zn(NO₃)₂), zinc nitrate hydrates (Zn(NO₃)₂.nH₂O), zinc carbonate (Zn(CO₃)), zinc acetylacetonate (Zn(CH₃COCHCOCH₃)₂) and zinc acetylacetonate hydrates (Zn(CH₃COCHCOCH₃)₂.nH₂O) may be used as the sol-gel precursor for ZnO, but it is not limited thereto.

In the case where the metal oxide is indium oxide (In₂O₃), at least one selected from the group consisting of indium nitrate hydrates (In(NO₃)₃.nH₂O), indium acetate (In(CH₃COO)₂), indium acetate hydrates (In(CH₃(COO)₂.nH₂O), indium chlorides (InCl, InCl₂, InCl₃), indium nitrate (In(NO₃)₃), indium nitrate hydrates (In(NO₃)₃.nH₂O), indium acetylacetonate (In(CH₃COCHCOCH₃)₂) and indium acetylacetonate hydrates (In(CH₃COCHCOCH₃)₂.nH₂O) may be used as the sol-gel precursor for In₂O₃.

In the case where the metal oxide is tin oxide (SnO₂), at least one selected from the group consisting of tin acetate (Sn(CH₃COO)₂), tin acetate hydrate (Sn(CH₃(COO)₂.nH₂O), tin chlorides (SnCl₂, SnCl₄), tin chloride hydrates (SnClₙ.nH₂O), tin acetylacetonate (Sn(CH₃COCHCOCH₃)₂) and tin acetylacetonate hydrates (Sn(CH₃COCHCOCH₃)₂.nH₂O) may be used as the sol-gel precursor for SnO₂.

In the case where the metal oxide is gallium oxide (Ga₂O₃), at least one selected from the group consisting of gallium nitrate (Ga(NO₃)₃), gallium nitrate hydrates (Ga(NO₃)₃.nH₂O), gallium acetylacetonate (Ga(CH₃COCHCOCH₃)₃), gallium acetylacetonate hydrates (Ga(CH₃COCHCOCH₃)₃.nH₂O) and gallium chlorides (Ga₂Cl₄, GaCl₃) may be used as the sol-gel precursor for Ga₂O₃.

In the case where the metal oxide is tungsten oxide (WO₃), at least one selected from the group consisting of tungsten carbide (WC), tungstic acid powder (H₂WO₄), tungsten chlorides (WCl₄, WCl₆), tungsten isopropoxide (W(OCH(CH₃)₂)₆), sodium tungstate (Na₂WO₄), sodium tungstate hydrates (Na₂WO₄.nH₂O), ammonium tungstate ((NH₄)₆H₂W₁₂O₄₀), ammonium tungstate hydrates ((NH₄)₆H₂W₁₂O₄₀.nH₂O) and tungsten ethoxide (W(OC₂H₅)₆) may be used as the sol-gel precursor for WO₃.

In the case where the metal oxide is an aluminum oxide, at least one selected from the group consisting of aluminum chloride (AlCl₃), aluminum nitrate (Al(NO₃)₃), aluminum nitrate hydrates (Al(NO₃)₃.nH₂O) and aluminum butoxide (Al(C₂H₅CH(CH₃)O)) may be used as the sol-gel precursor for an aluminum oxide.

In the case where the metal oxide is a titanium oxide, at least one selected from the group consisting of titanium isopropoxide (Ti(OCH(CH₃)₂)₄), titanium chloride (TiCl₄), titanium ethoxide (Ti(OC₂H₅)₄) and titanium butoxide (Ti(OC₄H₉)₄) may be used as the sol-gel precursor for a titanium oxide.

In the case where the metal oxide is a vanadium oxide, at least one selected from the group consisting of Vanadium(V) oxide isopropoxide (VO(OC₃H₇)₃), ammonium vanadate (NH₄VO₃), vanadium acetylacetonate (V(CH₃COCHCOCH₃)₃) and vanadium acetylacetonate hydrates (V(CH₃COCHCOCH₃)₃.nH₂O) may be selected as the sol-gel precursor for a vanadium oxide.

In the case where the metal oxide is a molybdenum oxide, at least one selected from the group consisting of molybdenum isopropoxide (Mo(OC₃H₇)₅), molybdenum chloride isopropoxide (MoCl₃(OC₃H₇)₂), ammonium molybdate ((NH₄)₂MoO₄) and ammonium molybdate hydrates ((NH₄)₂MoO₄.nH₂O) may be used as the sol-gel precursor for a molybdenum oxide.

In the case where the metal oxide is a copper oxide, at least one selected from the group consisting of copper chlorides (CuCl, CuCl₂), copper chloride hydrates (CuCl₂.nH₂O), copper acetates (Cu(CO₂CH₃), Cu(CO₂CH₃)₂), copper acetate hydrates (Cu(CO₂CH₃)₂.nH₂O), copper acetylacetonate (Cu(C₅H₇O₂)₂), copper nitrate (Cu(NO₃)₂), copper nitrate hydrates (Cu(NO₃)₂.nH₂O), copper bromides (CuBr, CuBr₂), basic copper carbonate (CuCO₃Cu(OH)₂), copper sulfides (Cu₂S, CuS), copper phthalocyanine (C₃₂H₁₆N₈Cu), copper trifluoroacetate (Cu(CO₂CF₃)₂), copper isobutyrate (C₈H₁₄CuO₄), copper ethyl acetoacetate (C₁₂H₁₈CuO₆), copper 2-ethylhexanoate ([CH₃(CH₂)₃CH(C₂H₅)CO₂]₂Cu), copper fluoride (CuF₂), copper formate hydrate ((HCO₂)₂CuH₂O), copper gluconate (C₁₂H₂₂CuO₁₄), copper hexafluoroacetylacetonate (Cu(C₅HF₆O₂)₂), copper hexafluoroacetylacetonate hydrates (Cu(C₅HF₆O₂)₂.nH₂O), copper methoxide (Cu(OCH₃)₂), copper neodecanoate (C₁₀H₁₉O₂Cu), copper perchlorate hydrate (Cu(ClO₄)₂6H₂O), copper sulfate (CuSO₄), copper sulfate hydrates (CuSO₄.nH₂O), copper tartrate hydrates ([⁻CH(OH)CO₂]₂Cu.nH₂O), copper trifluoroacetylacetonate (Cu(C₅H₄F₃O₂)₂), copper trifluoromethanesulfonate ((CF₃SO₃)₂Cu) and tetraamine copper sulfate hydrate (Cu(NH₃)₄SO₄H₂O) may be used as the sol-gel precursor of a copper oxide.

In the case where the metal oxide is a nickel oxide, at least one selected from the group consisting of nickel chloride (NiCl₂), nickel chloride hydrates (NiCl₂.nH₂O), nickel acetate hydrate (Ni(OCOCH₃)₂4H₂O), nickel nitrate hydrate (Ni(NO₃)₂6H₂O), nickel acetylacetonate (Ni(C₅H₇O₂)₂), nickel hydroxide (Ni(OH)₂), nickel phthalocyanine (C₃₂H₁₆N₈Ni) and nickel carbonate basic hydrates (NiCO₃2Ni(OH)₂.nH₂O) may be used as the sol-gel precursor of a nickel oxide.

In the case where the metal oxide is an iron oxide, at least one selected from the group consisting of iron acetate (Fe(CO₂CH₃)₂), iron chlorides (FeCl₂, FeCl₃), iron chloride hydrates (FeCl₃.nH₂O), iron acetylacetonate (Fe(C₅H₇O₂)₃), iron nitrate hydrate (Fe(NO₃)₃9H₂O), iron phthalocyanine (C₃₂H₁₆FeN₈), iron oxalate hydrates (Fe(C₂O₄).nH₂O and Fe₂(C₂O₄)₃6H₂O) may be used as the sol-gel precursor of an iron oxide.

In the case where the metal oxide is a chromium oxide, at least one selected from the group consisting of chromium chlorides (CrCl₂, CrCl₃), chromium chloride hydrates (CrCl₃.nH₂O), chromium carbide (Cr₃C₂), chromium acetylacetonate (Cr(C₅H₇O₂)₃), chromium nitrate hydrates (Cr(NO₃)₃.nH₂O), chromium acetate hydroxide ((CH₃CO₂)₇Cr₃(OH)₂) and chromium acetate hydrate ([(CH₃CO₂)₂CrH₂O]₂) may be used as the sol-gel precursor of a chromium oxide.

In the case where the above-described metal oxide is a bismuth oxide, at least one selected from the group consisting of bismuth chloride (BiCl₃), bismuth nitrate hydrates (Bi(NO₃)₃.nH₂O), bismuth acetate ((CH₃CO₂)₃Bi) and bismuth carbonate ((BiO)₂CO₃) may be used as the sol-gel precursor of a bismuth oxide.

In the case where metal oxide nanoparticles are contained in the above-described liquid mixture for an electron injection layer, the average particle diameter of the above-described metal oxide nanoparticles may be 10 nm to 100 nm.

The above-described solvent may be a polar solvent or a non-polar solvent. For example, examples of the polar solvent include alcohols, ketones, etc., and examples of the non-polar solvent include the organic solvents which are based on aromatic hydrocarbons, alicyclic hydrocarbons or aliphatic hydrocarbons. As an example, the solvent may be one or more type selected among ethanol, dimethylformamide, methanol, propanol, butanol, isopropanol, methyl ethyl ketone, propylene glycol (mono)methyl ether (PGM), isopropyl cellulose (IPC), methyl cello solve (MC), ethylene carbonate (EC), 2-methoxyethanol, 2-ethoxyethanol and ethanolamine, but it is not limited thereto.

For example, in the case where the electron injection layer 31 consisting of ZnO is formed, the above-described mixture for the electron injection layer may contain zinc acetate dehydrate as the precursor for ZnO and may contain a combination of 2-methoxyethanol and ethanol amine as the solvent, but it is not limited thereto.

The conditions of the above-mentioned heat treatment may differ depending on the type and quantity of the selected solvent, but typically, it is preferable to carry out the heat treatment within the ranges of 100° C. to 350° C. and of 0.1 hours to 1 hour. In the case where the temperature and duration of the above-mentioned heat treatment satisfy these ranges, solvent removal can be thoroughly effective and also the device will not be deformed.

In the case where the electron injection layer 31 is formed by using a deposition method, the deposition is possible in various methods well-known in the art, such as, an electron beam deposition method, a thermal evaporation method, a sputter deposition method, an atomic layer deposition method and a chemical vapor deposition method. The conditions of deposition vary depending on the target compound and the structure, thermal properties, etc. of the target layer, but it is preferable to carry out deposition, for example, in the deposition temperature range of 25 to 1500° C., more specifically, of 100 to 500° C., the vacuum degree range of 10⁻¹⁰ to 10⁻³ torr and the deposition rate range of 0.01 to 100 Å/sec.

The thickness of the electron injection layer 31 may be 10 nm to 100 nm, and, more specifically, 20 nm to 50 nm. In the case where the thickness of the electron injection layer 31 satisfies the range described above, electron injection is facilitated so that a high quality organic light emitting diode can be provided without an actual increase in the driving voltage.

An electron injection interface layer 33, which contains a polymer being capable of inducing an interface dipole by bonding with the oxygen of the above-described metal oxide, can be formed on the electron injection layer 31. The polymer is a material whose dipole moment is not 0 and may contain a nitrogen atom. For example, it may be a polymer containing an amine group (more specifically, a primary amine group, a secondary amine group or a tertiary amine group), an azo group or an ammonium group. Such a nitrogen atom (for example, an amine group, an azo group or an ammonium group) may be contained in at least one or more for every repeat unit of the polymer. In addition, a nitrogen atom (for example, an amine group, an azo group or an ammonium group) may be contained in the main chain or may be contained in the side chain of the polymer.

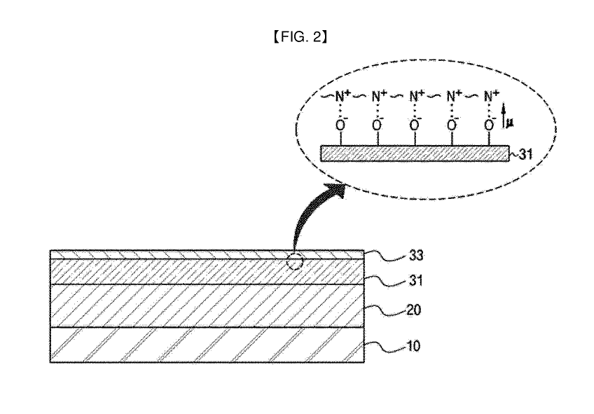

FIG. 2 is a cross-sectional view showing an enlarged interface between the electron injection layer 31 and the electron injection interface layer 33.

Referring to FIG. 2, oxygen on the surface of the electron injection layer 31 containing a metal oxide can form an interface dipole by bonding with nitrogen of the electron injection interface layer 33. The dipole moment of such an interface dipole is directed toward the light emitting layer which will be described later. Therefore, deformation of a vacuum level may occur, and accordingly, the electron injection layer 31 having the electron injection interface layer 33 formed on its surface may experience decrease in its work function. Therefore, by making changes to the work-function of the electron injection layer 31, it is possible to reduce an electron injection barrier, and, consequentially, reduce the driving voltage.

In addition, the bonding between oxygen on the surface of the electron injection layer 31 containing a metal oxide and nitrogen of the electron injection interface layer 33 can cause the polymer in the electron injection interface layer 33 to self-assemble on the electron injection layer 31.

Referring again to FIG. 1b, the above-described polymer in the electron injection interface layer 33 may be a dielectric polymer. As an example, the polymer may be a non-conjugated polymer. In this case, an electron may tunnel through the electron injection interface layer 33. However, the dielectric property of the electron injection interface layer 33 can prevent holes from flowing from the light emitting layer. In other words, the electron injection interface layer 33 can serve as a hole blocking layer. In addition, through inhibition of exciton dissociation which takes place on a surface of the electron injection layer 31, an electron-hole recombination rate increases, and thus, luminance efficiency increases.

The dipole moment of an interface dipole which the electron injection interface layer 33 induces may decrease with increased thickness. As the thickness of the electron injection interface layer 33 increases, dipole moments that nitrogen atoms in the polymer induce are not directed towards the light emitting layer only but positioned randomly, and therefore, the dipole moments offset each other. As the thickness of the electron injection interface layer 33 increases, the surface dipole moment decreases, and thus, the amount of reduction in work function of the electron injection layer 31 below may decrease.

Therefore, the electron injection interface layer 33 may have a thickness of 1 nm to 20 nm, for example, 4 nm to 16 nm, more specifically, 8 nm to 16 nm, and even more specifically, 8 nm to 12 nm. In the case where such a range of thickness is satisfied, not only does the formation of interface dipoles become facilitated, but also mutual offsetting of formed interface dipoles become reduced, hole blocking and exciton dissociation blocking properties may be observed.

The above-described polymer may be a polyethylenimine-based polymer or a polyallylamine polymer. As an example, the polymer may contain at least one selected from the group consisting of branched polyethyleneimine, polyethyleneimine ethoxylated, poly(2-ethyl-2-oxazolines), linear polyethyleneimine, bioreducible disulfide-crosslinked polyethyleneimine, polyethyleneimine max, polyallylamine, polyallylamine hydrochloride, poly(1-(4-(3-carboxy-4hydroxyphenylazo)benzenesulfonamido)-1,2-ethanediyl, sodium salt) and poly(diallyldimethylammonium chloride).

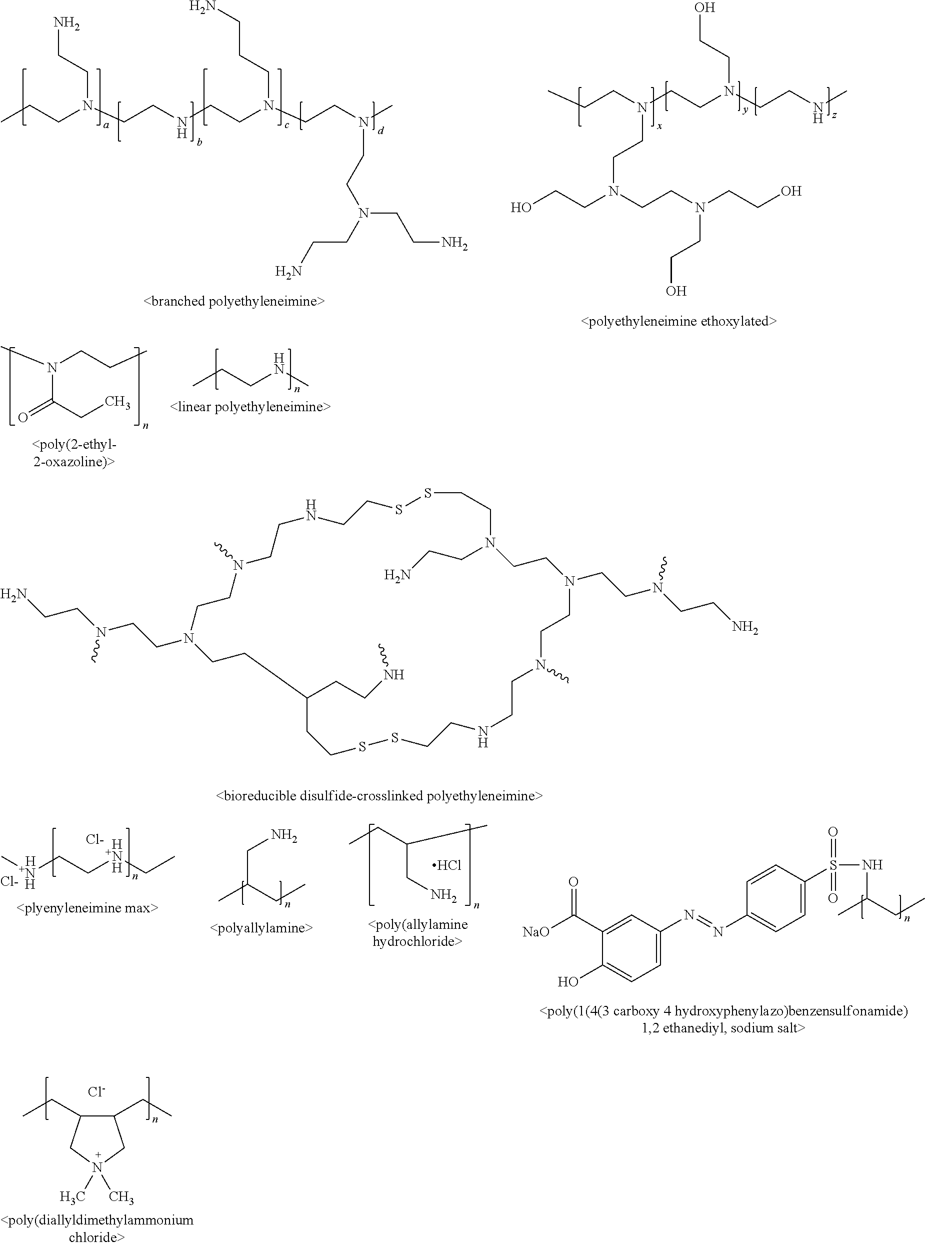

It is preferable that the electron injection interface layer 33 is formed by a solution process.

At first, the above-described solution process prepares a liquid mixture by mixing the above-described polymer, which contains a nitrogen atom, with a solvent. In this case, it is preferable that the polymer which contains a nitrogen atom is a material having solubility in a polar solvent of 90% or more, for example, 95% or more. Examples of the polar solvent may include, but are not limited to, water, alcohol (methanol, ethanol, n-propanol, 2-propanol, n-butanol, etc.), formic acid, nitromethane, acetic acid, ethylene glycol, glycerol, normal methyl pyrrolidone (NMP, n-Methyl-2-Pyrrolidone), N.N-dimethylacetamide, dimethylformamide (DMF), dimethyl sulfoxide (DMSO), tetrahydrofuran (THF), ethyl acetate (EtOAc), acetone, acetonitrile (MeCN), etc.

Thereafter, the electron injection interface layer 33 may be formed by applying the above-described mixed solution on the electron injection layer 31, and then, removing the above-described solvent by a heat treatment.

An electron transporting layer (not shown) may be additionally formed on the electron injection interface layer 33.

As for the material for forming the above-described electron transporting layer, an electron transporting material well-known in the art may be used.

For example, the above-described electron transporting layer may include a quinoline derivative, especially, tris(8-hydroxyquinoline)aluminum (Alq₃), bis(2-methyl-8-quinolinolate)-4-(phenylphenolato)aluminum (Balq), bis(10-hydroxybenzo[h]quinolinato)-beryllium (Bebq₂), 2,9-dimethyl-4,7-diphenyl-1,10-phenanthroline (BCP), 4,7-diphenyl-1,10-phenanthroline (Bphen), (2,2′,2″-(benzene-1,3,5-triyl)-tris(1-phenyl-1H-benzimidazole) (TPBI), 3-(4-biphenyl)-4-phenyl-5-tert-butylphenyl-1,2,4-triazole (TAZ), 4-(naphthalen-1-yl)-3,5-diphenyl-4H-1,2,4-triazole (NTAZ), 2,9-bis(naphthalen-2-yl)-4,7-diphenyl-1,10-phenanthroline (NBphen), tris(2,4,6-trimethyl-3-(pyridin-3-yl)phenyl)borane (3TPYMB), phenyl-dipyrenylphosphine oxide (POPy2), 3,3′,5,5′-tetra[(m-pyridyl)-phen-3-yl]biphenyl (BP4mPy), 1,3,5-tri[(3-pyridyl)-phen-3-yl]benzene (TmPyPB), 1,3-bis[3,5-di(pyridin-3-yl)phenyl]benzene (BmPyPhB), bis(10-hydroxybenzo[h]quinolinato)beryllium (Bepq2), diphenylbis(4-(pyridin-3-yl)phenyl)silane (DPPS) and 1,3,5-tri(p-pyrid-3-yl-phenyl)benzene (TpPyPB), 1,3-bis[2-(2,2′-bipyridine-6-yl)-1,3,4-oxadiazo-5-yl]benzene (Bpy-OXD), 6,6′-bis[5-(biphenyl-4-yl)-1,3,4-oxadiazo-2-yl]-2,2′-bipyridyl (BP-OXD-Bpy), etc.

The chemical formulae of the above-described materials are as follows:

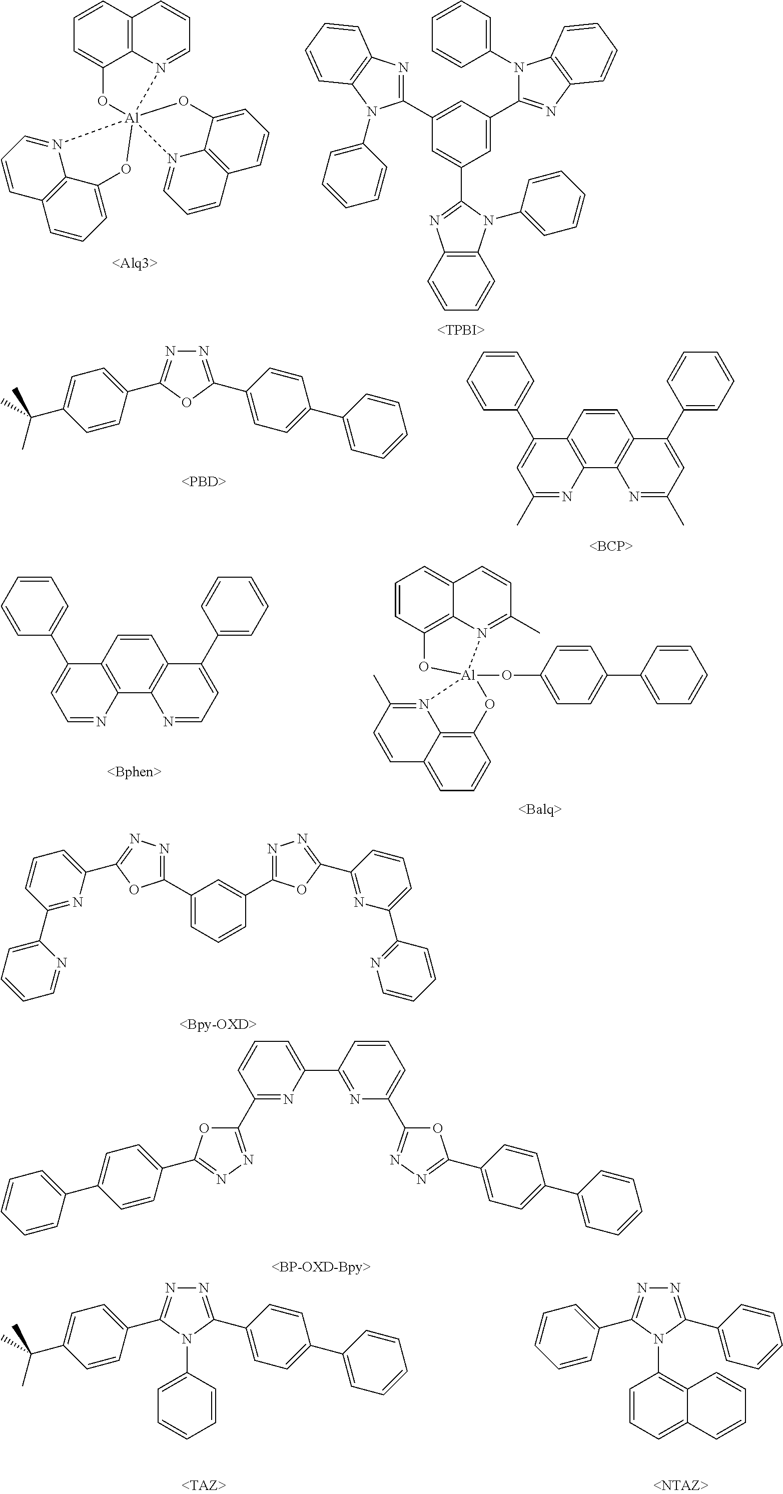

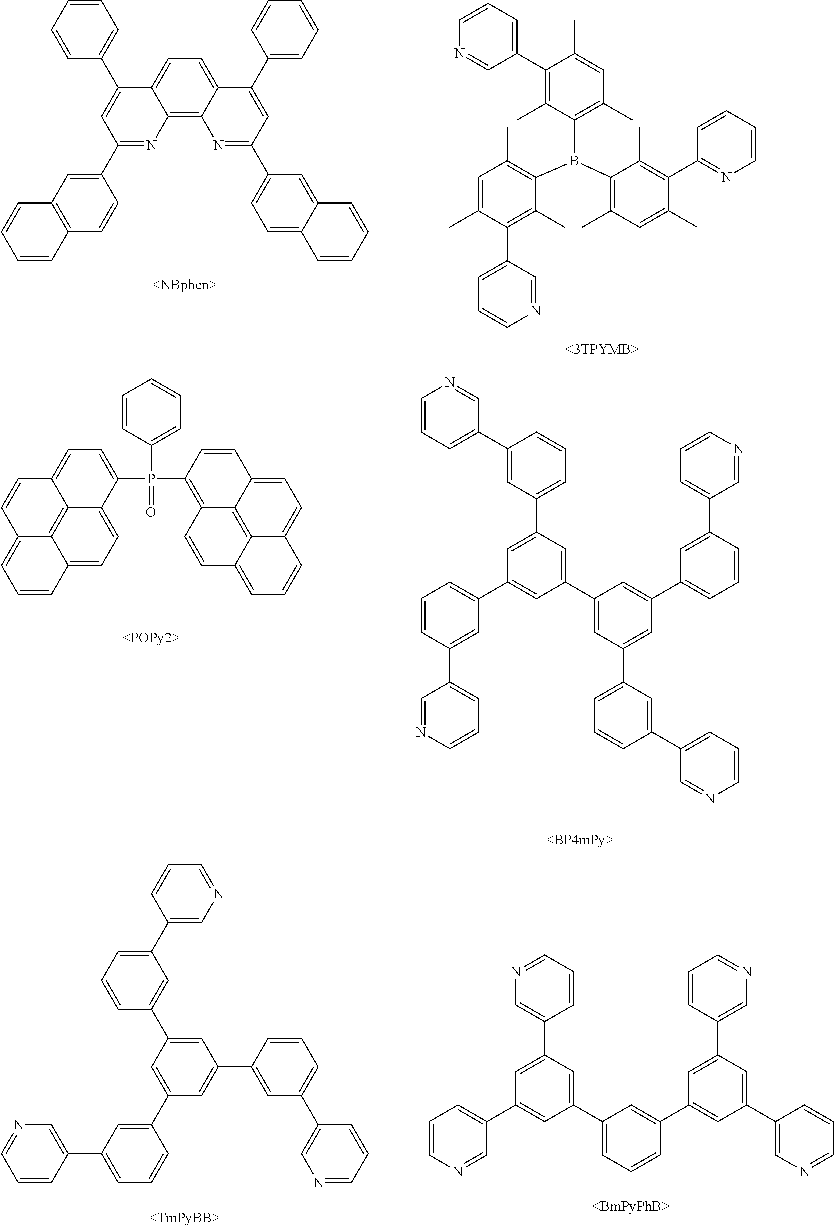 [SMILES: c1ccc(-c2cc(-c3ccc4ccccc4c3)nc3c2ccc2c(-c4ccccc4)cc(-c4ccc5ccccc5c4)nc23)cc1 ; Cc1cc(C)c(-c2cccnc2)c(C)c1B(c1c(C)cc(C)c(-c2cccnc2)c1C)c1c(C)cc(C)c(-c2ccccn2)c1C ; O=P(c1ccccc1)(c1ccc2ccc3cccc4ccc1c2c34)c1ccc2ccc3cccc4ccc1c2c34 ; c1cncc(-c2cccc(-c3cc(-c4cccc(-c5cccnc5)c4)cc(-c4cc(-c5cccc(-c6cccnc6)c5)cc(-c5cccc(-c6cccnc6)c5)c4)c3)c2)c1 ; c1cncc(-c2cccc(-c3cc(-c4cccc(-c5cccnc5)c4)cc(-c4cccc(-c5cccnc5)c4)c3)c2)c1 ; c1cncc(-c2cc(-c3cccnc3)cc(-c3cccc(-c4cc(-c5cccnc5)cc(-c5cccnc5)c4)c3)c2)c1]

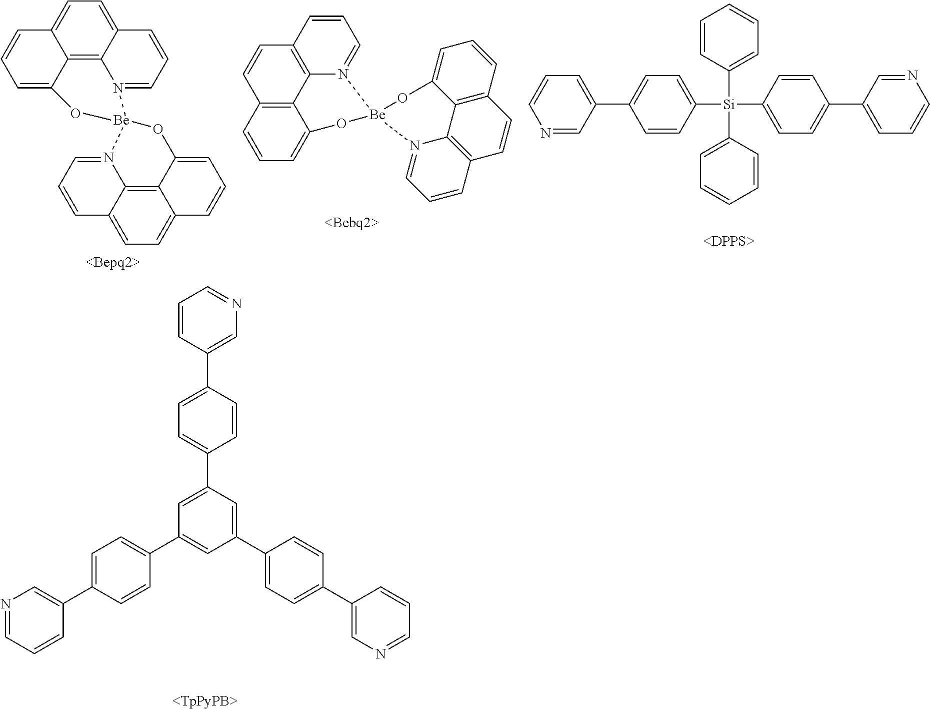

The thickness of the above-described electron transporting layer may be about 5 nm to 100 nm, for example, 15 nm to 60 nm. In the case where the thickness of the electron transporting layer satisfies the range as described above, an excellent electron transporting property can be obtained without an increase in the driving voltage.

Referring to FIG. 1c, a light emitting layer 50 may be formed on the above-described electron transporting layer or, in the case where the electron transporting layer is omitted, on the electron injection interface layer 33.

As for the material making up the light emitting layer, any low-molecular-weight light emitting material and/or polymer light emitting material may be used.

The light emitting layer 50 may be formed by any method selected among various methods which are well-known in the art, such as, a vacuum deposition method, a spin coating method, a casting method, a Langmuir-Blodgett (LB) method, a spray coating method, a dip coating method, a gravure coating method, a reverse offset coating method, a screen printing method, a slot-die coating method and a nozzle printing method. In this case, when a vacuum deposition method is selected, the deposition conditions vary depending on the target compound and the structure, thermal properties, etc. of the target layer, thermal properties, etc., but it is preferable that it is carried out, for example, in the deposition temperature range of 100 to 500° C., the vacuum degree range of 10⁻¹⁰ to 10⁻³ torr and the deposition rate range of 0.01 to 100 Å/sec. In the case where a spin coating method is used, the coating conditions vary depending on the target compound and the structure and thermal properties of the target layer, but it is preferable that it is carried out in the coating rate range of 2000 rpm to 5000 rpm and the heat treatment temperature (i.e. heat treatment temperature for solvent removal after coating) range of 80° C. to 200° C.

The light emitting layer 50 may consist of a single light emitting material, or it may contain a host and a dopant.

As for the above-described host, at least one selected from the group consisting of Alq₃, CBP (4,4′-N,N′-dicarbazole-biphenyl), 9,10-di(naphth-2-yl) anthracene (ADN), TCTA, TAPC, TPBI (1,3,5-tris(N-phenylbenzimidazole-2-yl)benzene)), TBADN (3-tert-butyl-9,10-di(naphth-2-yl) anthracene), E3 (see the chemical formula below) and BeBq₂ (see the chemical formula above) may be used, but it is not limited thereto.

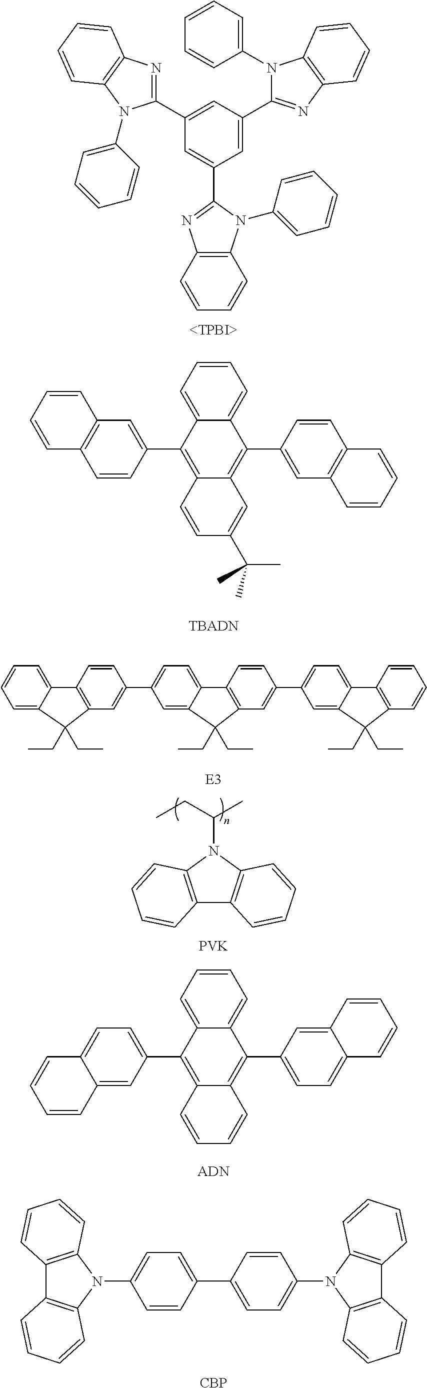

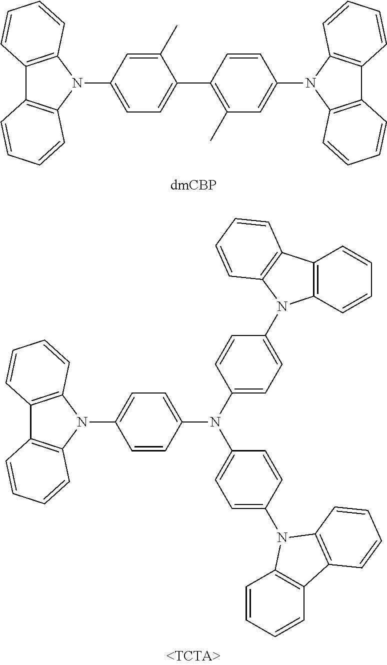 [SMILES: Cc1cc(-n2c3ccccc3c3ccccc32)ccc1-c1ccc(-n2c3ccccc3c3ccccc32)cc1C ; "dmCBP" ; c1ccc2c(c1)c1ccccc1n2-c1ccc(N(c2ccc(-n3c4ccccc4c4ccccc43)cc2)c2ccc(-n3c4ccccc4c4ccccc43)cc2)cc1]

As for a blue dopant among the above-described dopants, the following compounds may be used, but it is not limited thereto.

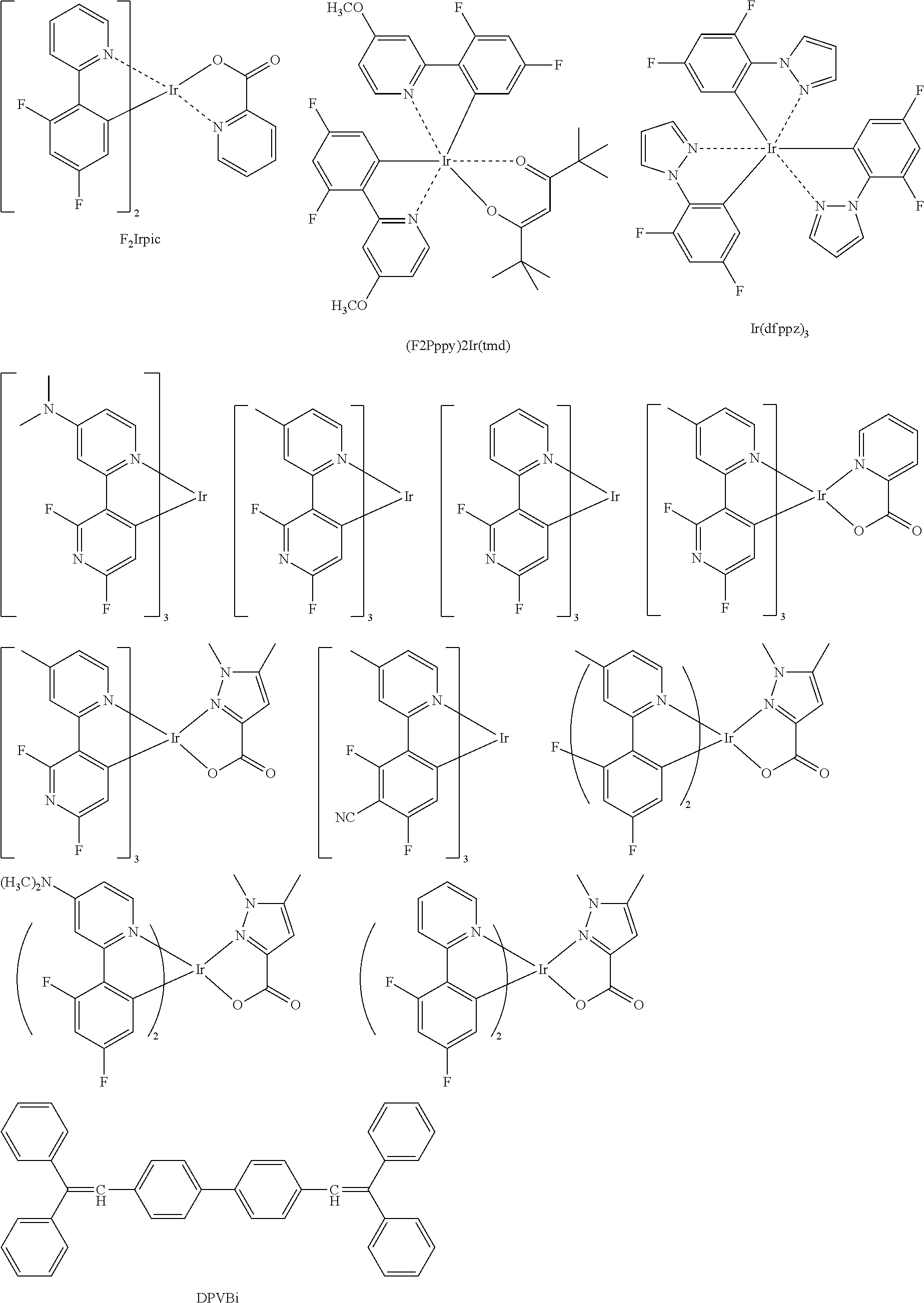

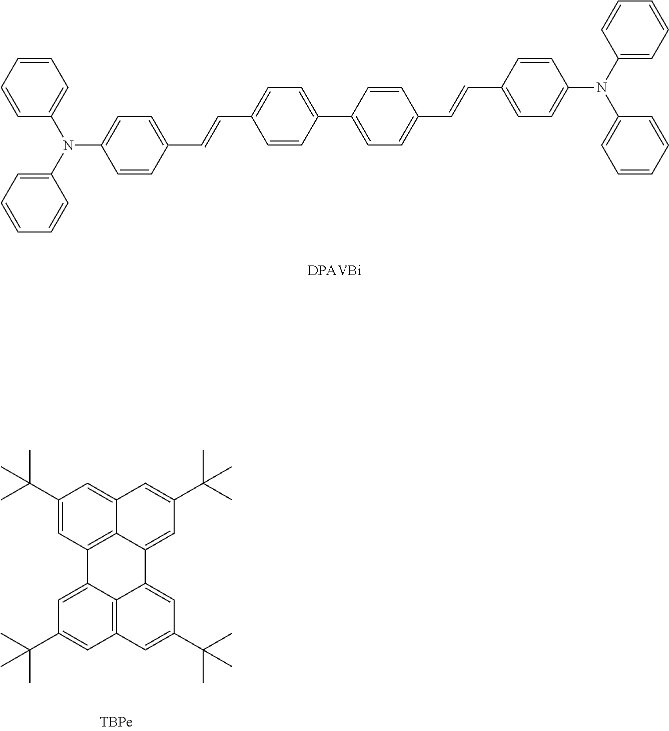

As for a red dopant among the above-described dopants, the following compounds may be used, but it is not limited thereto. Alternatively, as the red dopant, DCM or DCJTB, which will be discussed later, may be used.

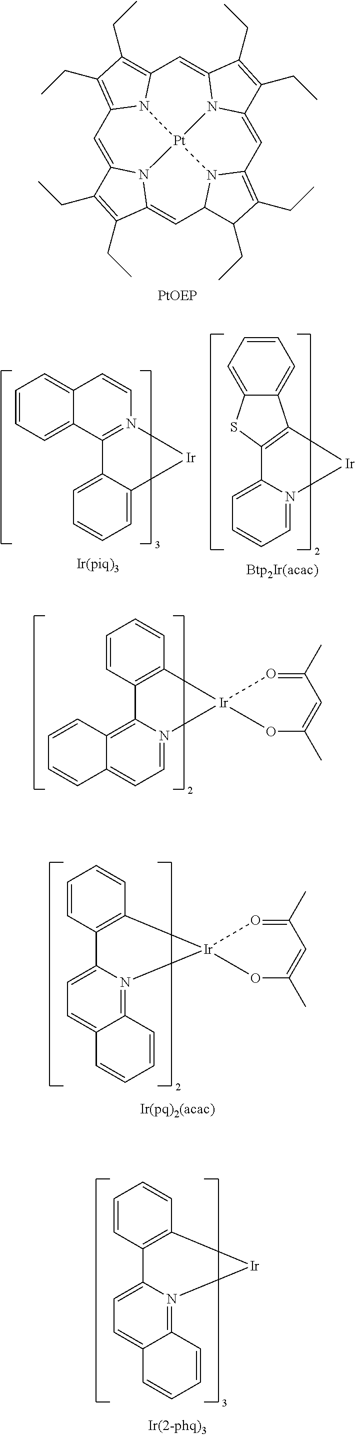

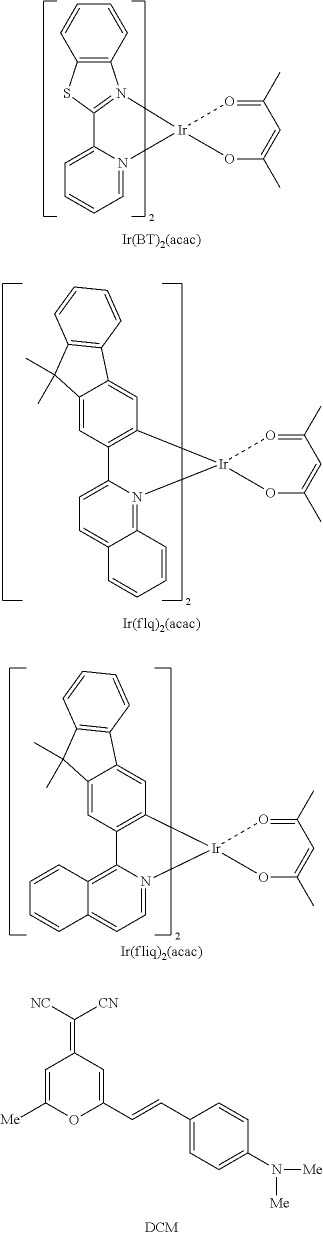

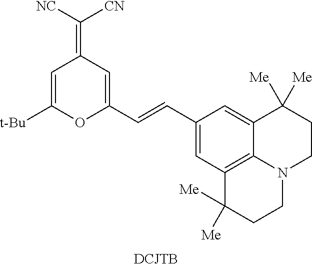 [SMILES: CC(C)(C)C1=CC(=C(C#N)C#N)C=C(/C=C/c2cc3c4c(c2)C(C)(C)CCN4CCC3(C)C)O1]

As for a green dopant among the above-described dopants, the following compounds may be used, but it is not limited thereto. Also, as the green dopant, C545T below may be used.

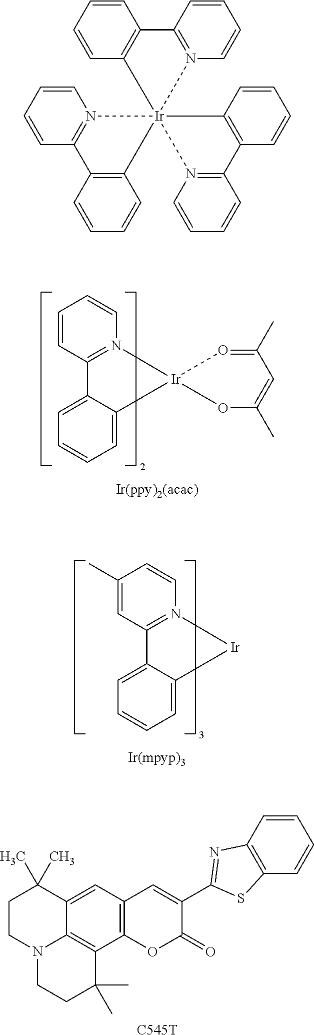

On the other hand, the light emitting layer 50 may be the derivative or co-polymer of a conjugated polymer such as a polyfluorene, a polyspirofluorene, a poly(p-phenylene vinylene), a poly(p-phenylene), a polythiophene and a polycarbazole. The light emitting layer may contain both fluorescence and phosphorescence. Also, it is possible that the polymer is a non-conjugated polymer to which fluorescent or phosphorescent chromophore group is grafted. For example, a polymer, which is represented by one of the chemical formulae illustrated in Chemical Formulas 100, 101, 102 and 103 below, may be included, but it is not limited thereto.

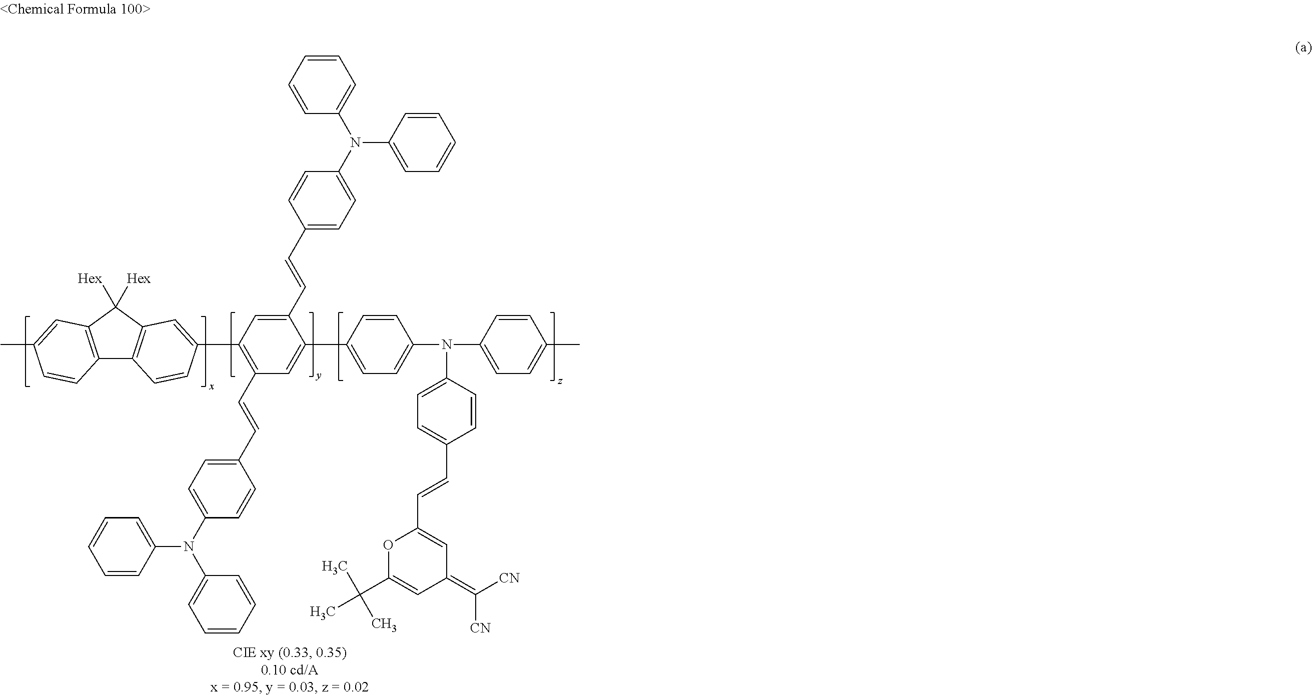

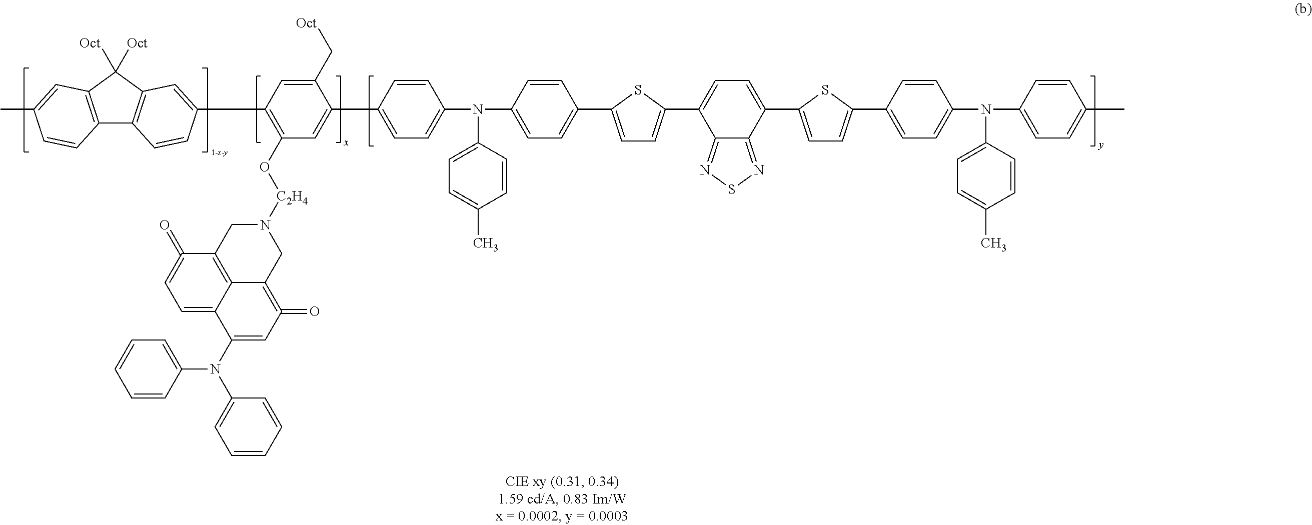

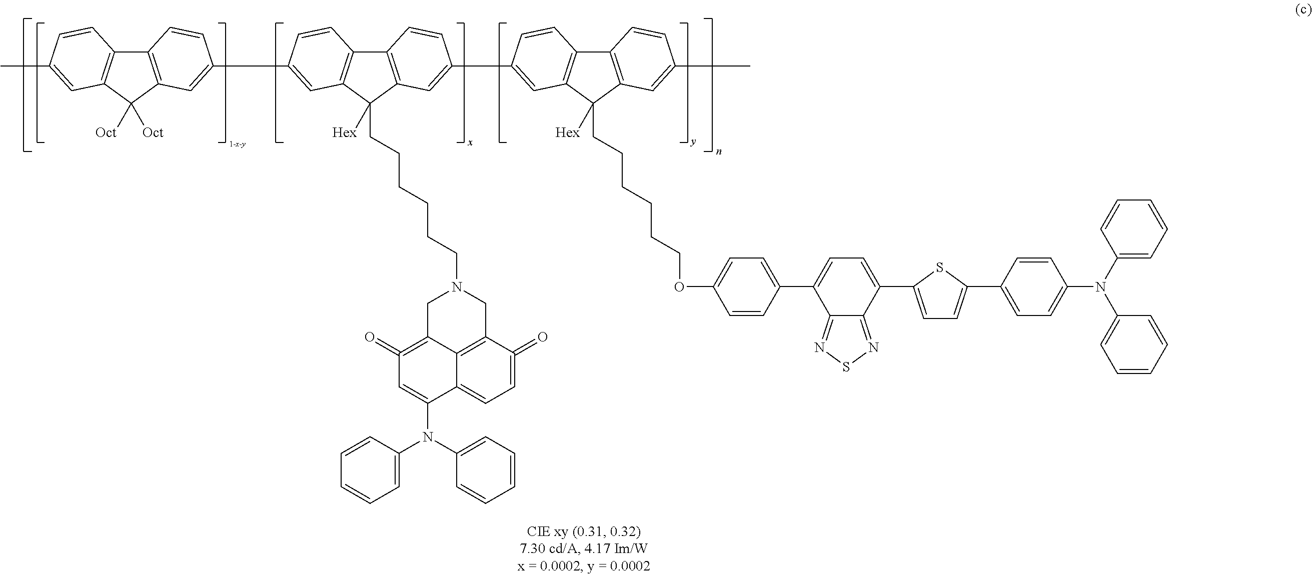

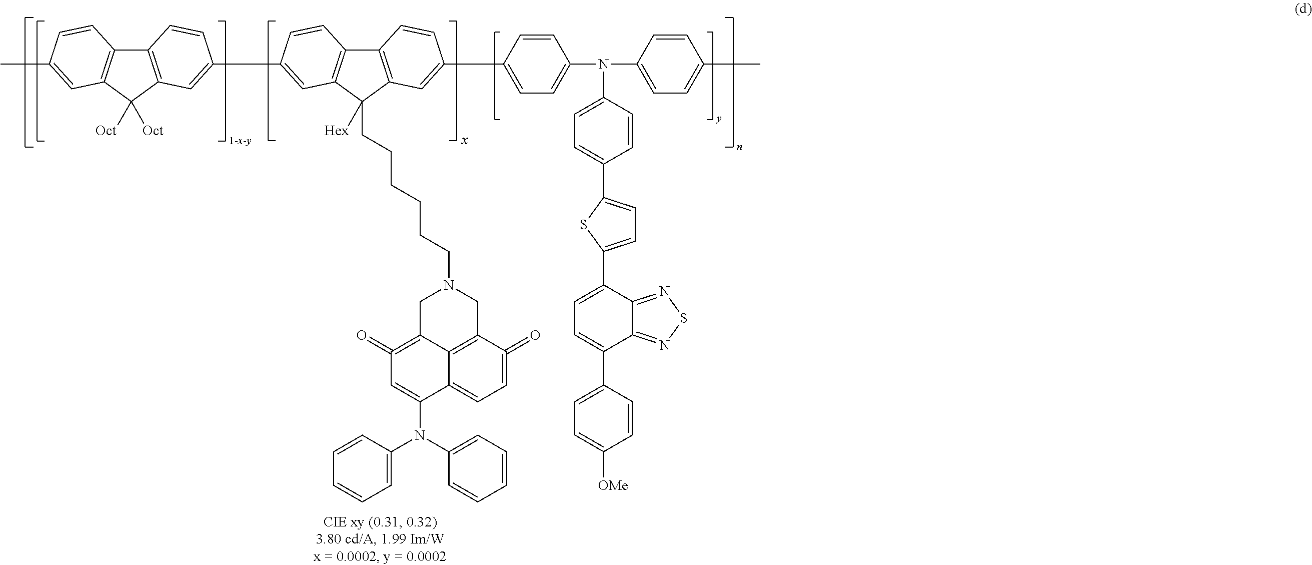

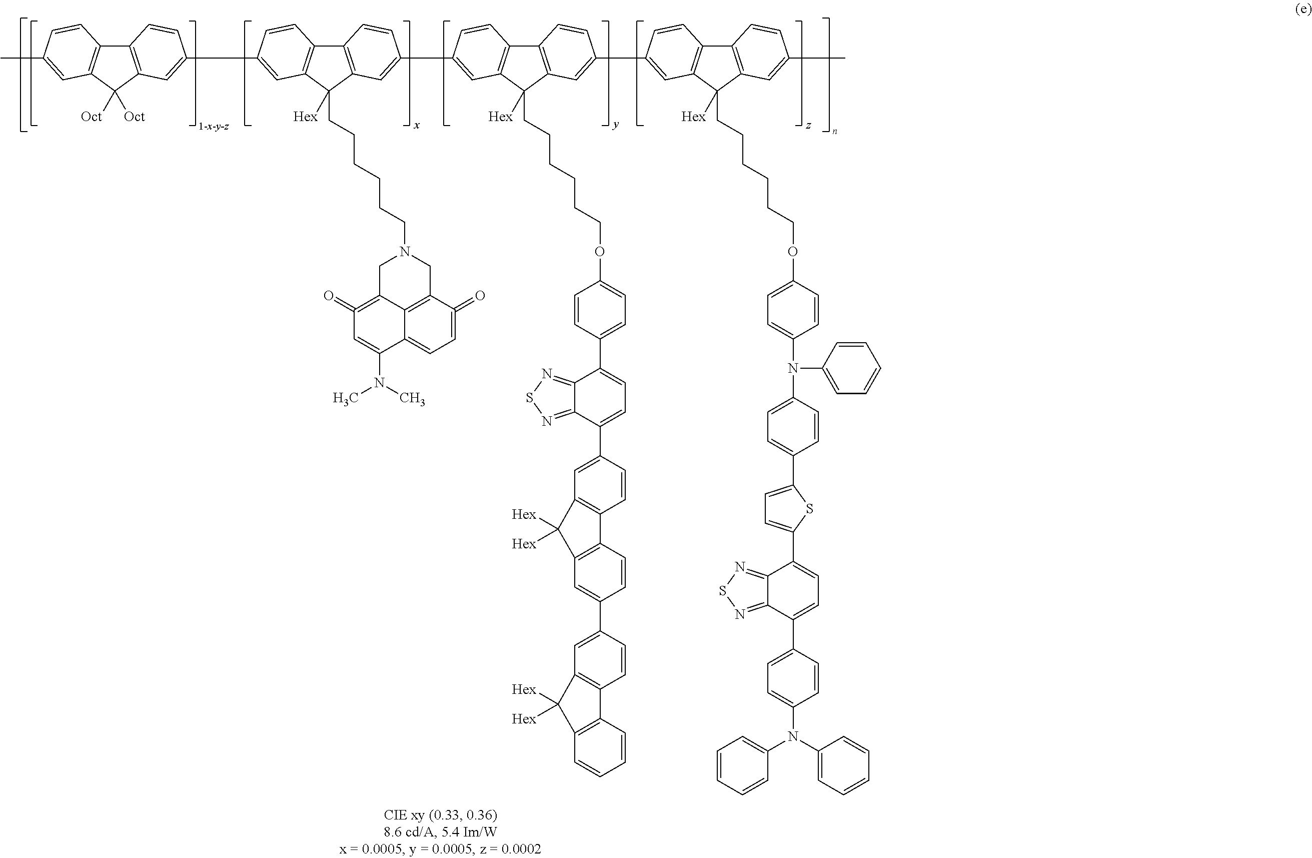

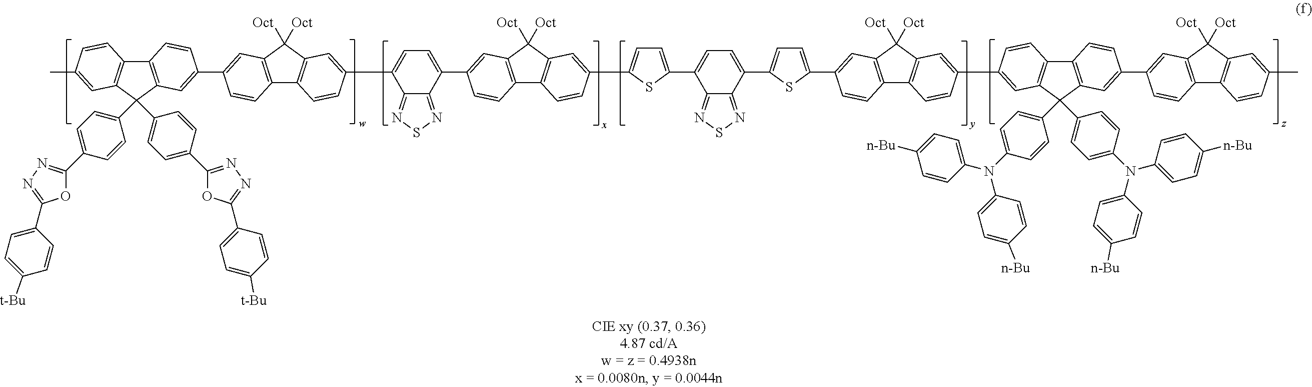

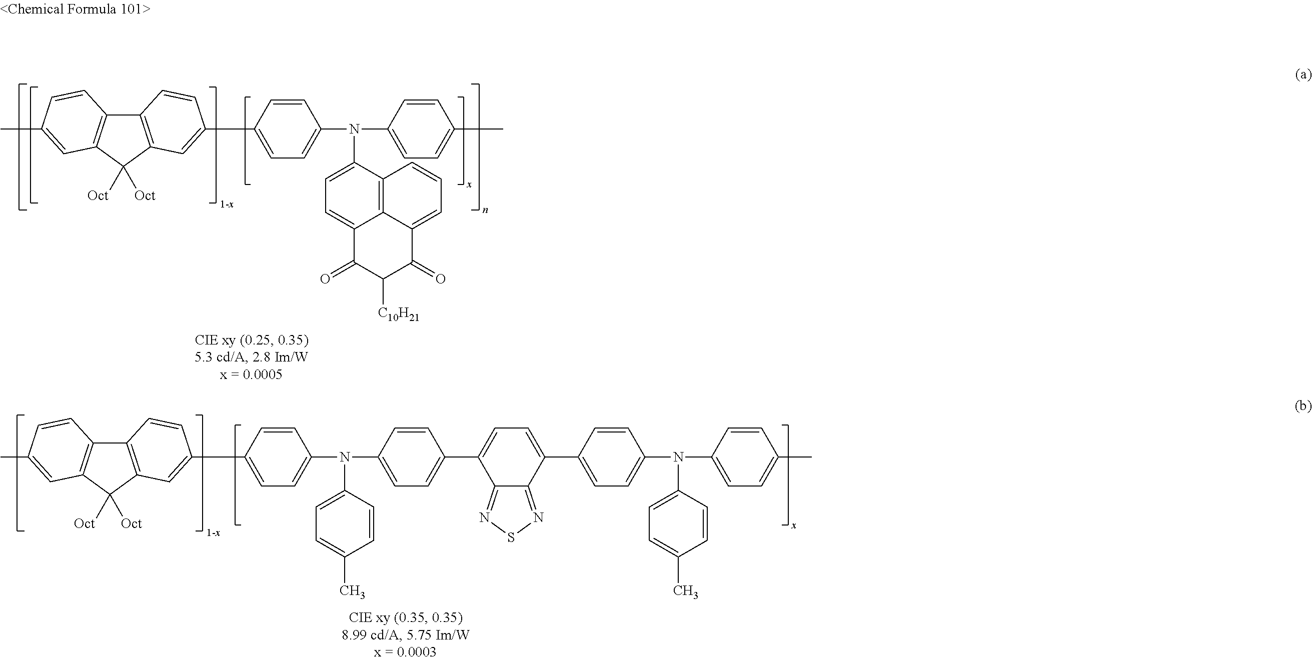

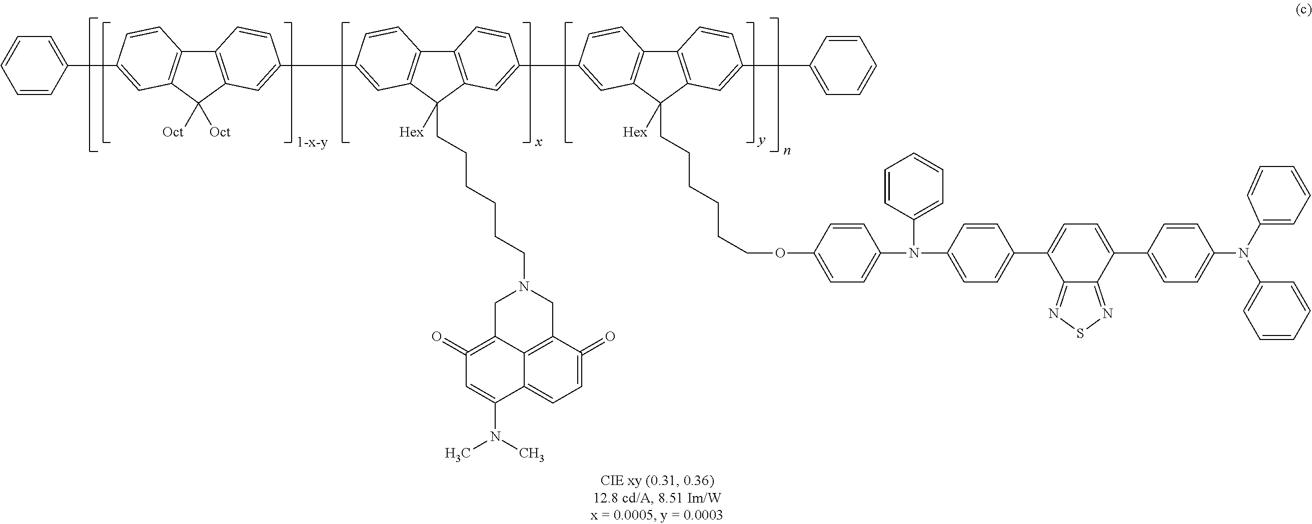

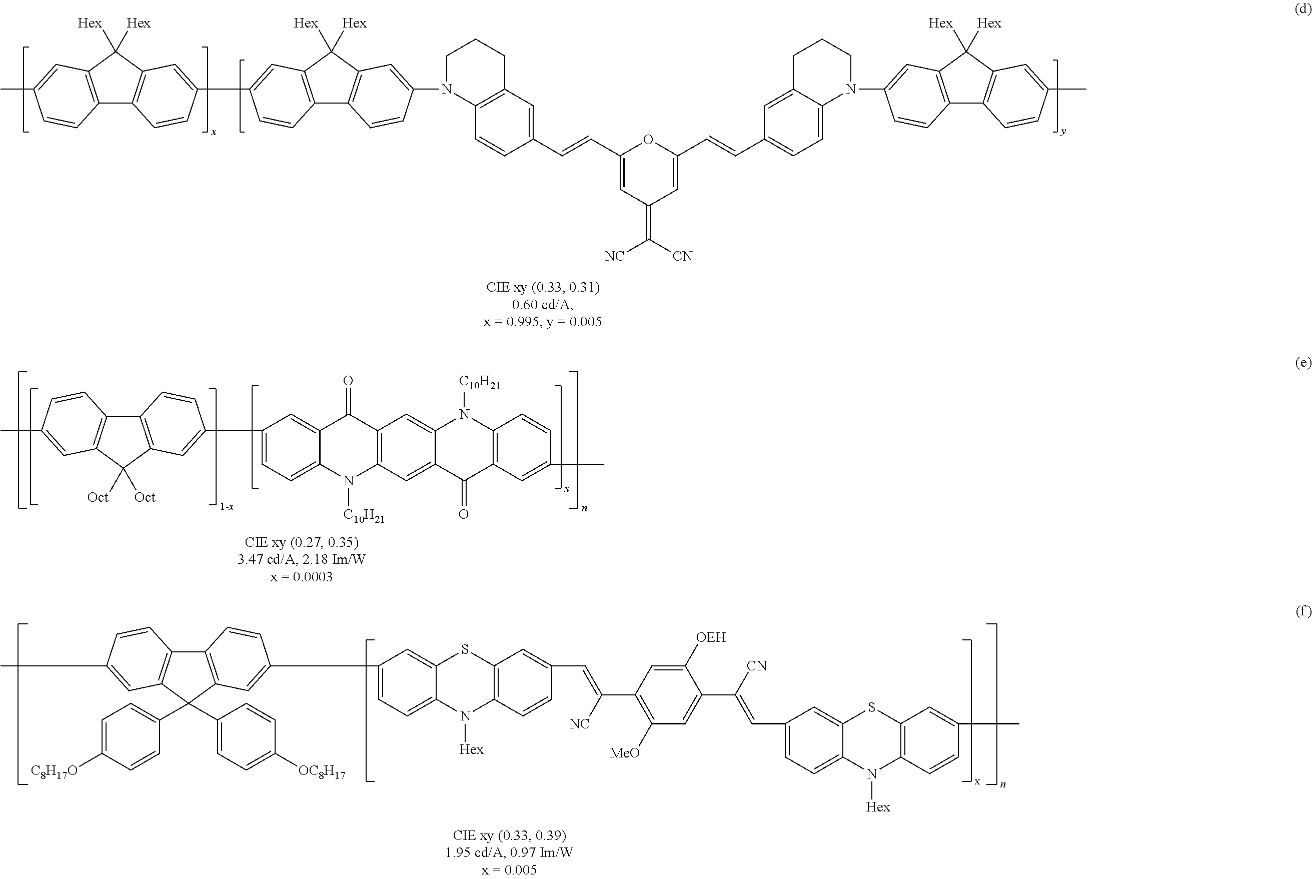

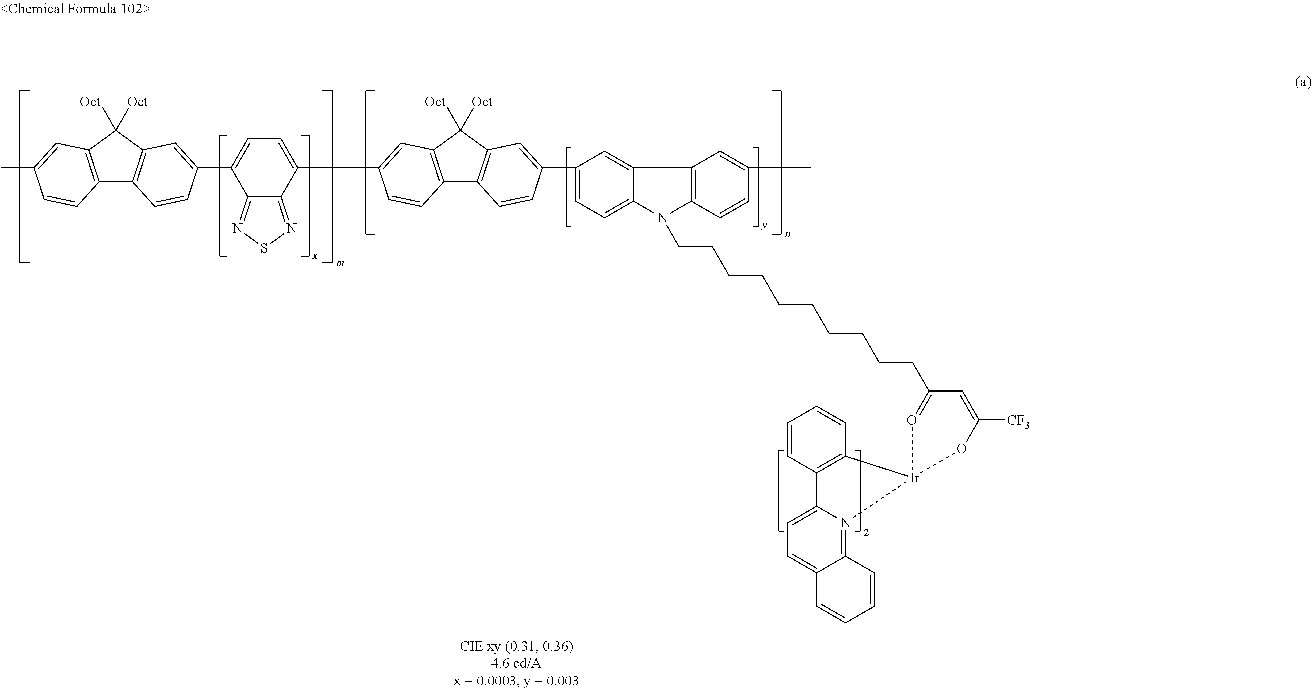

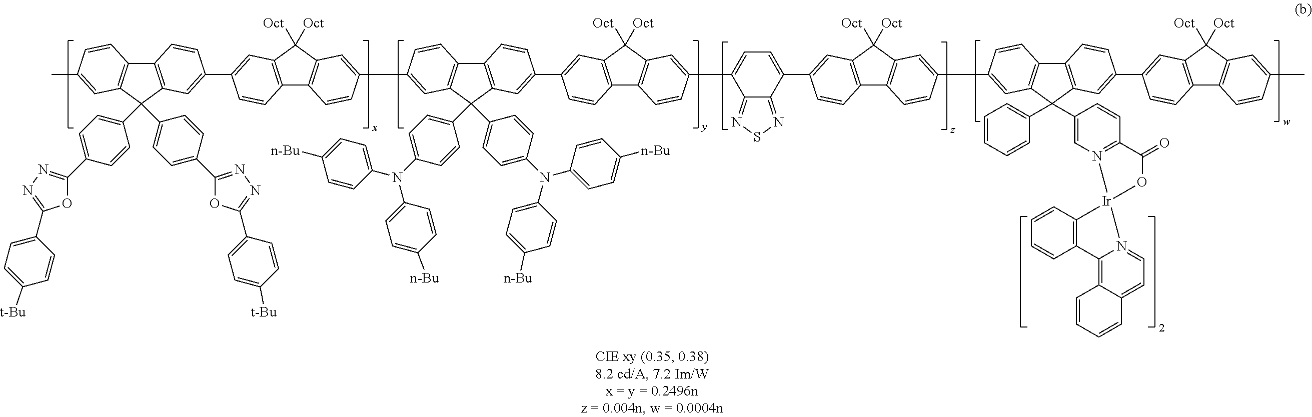

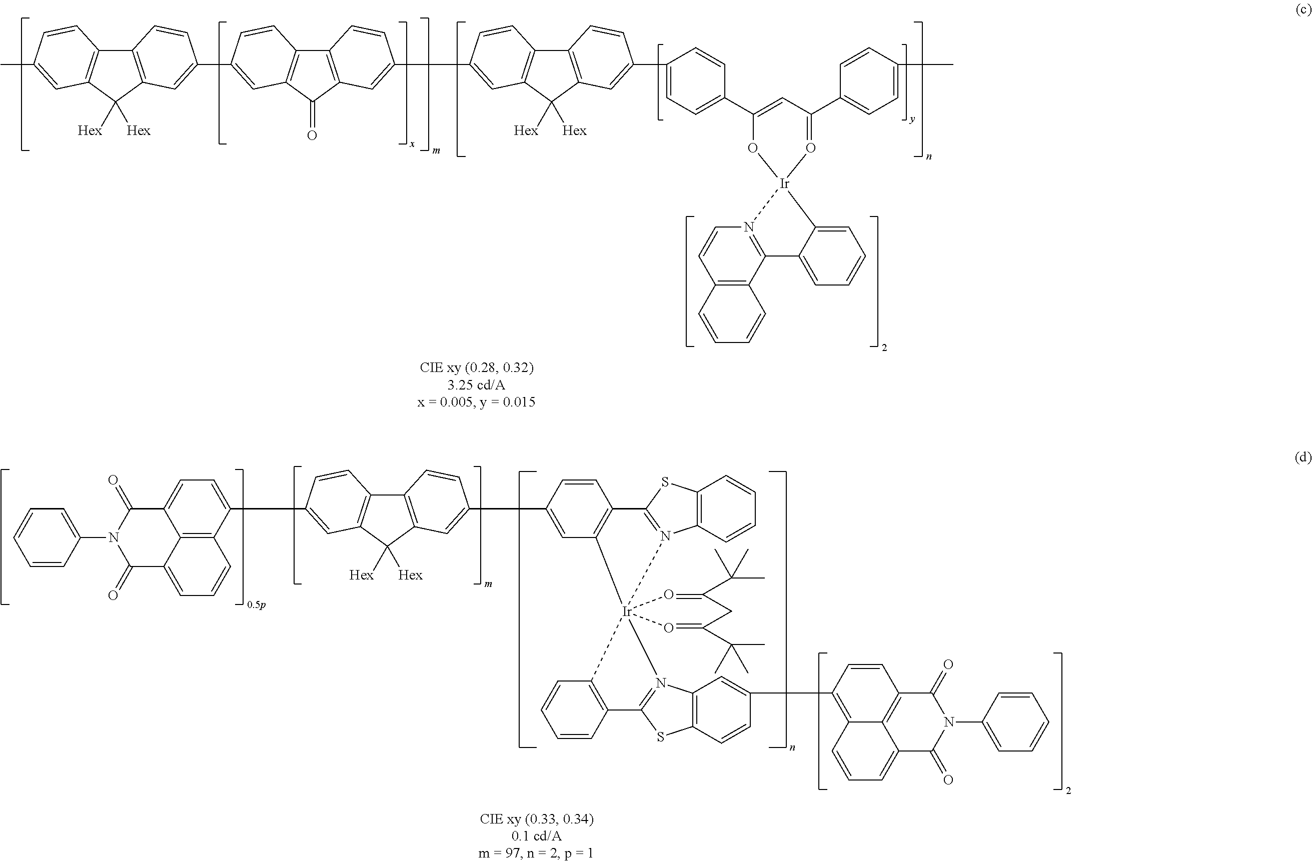

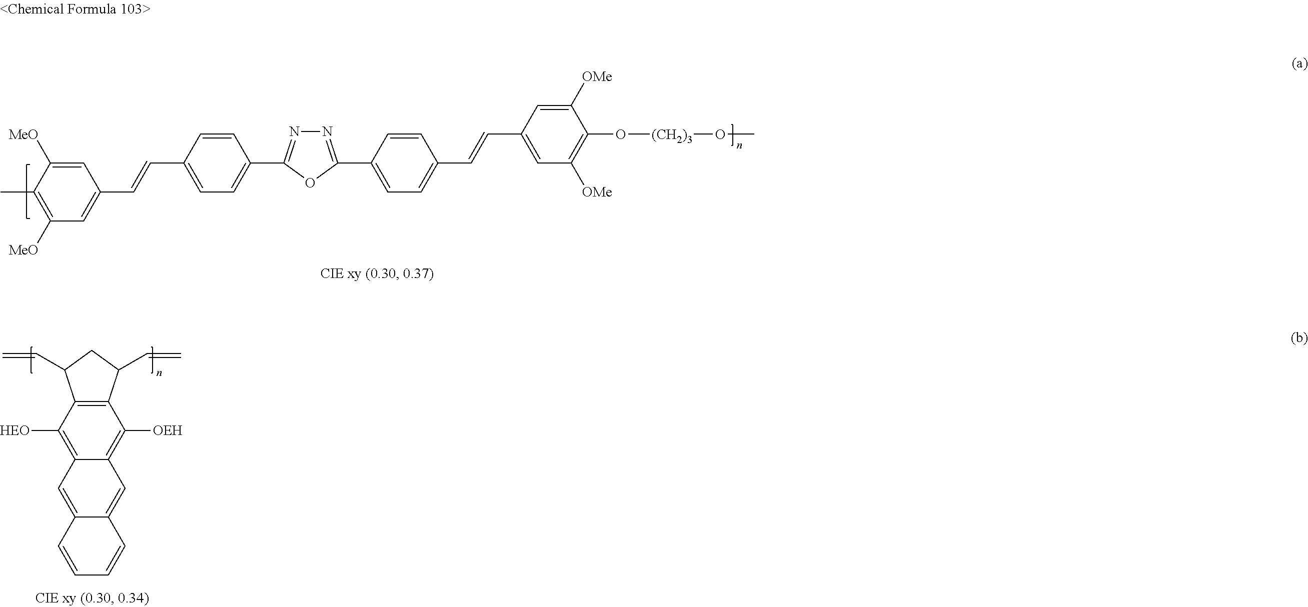

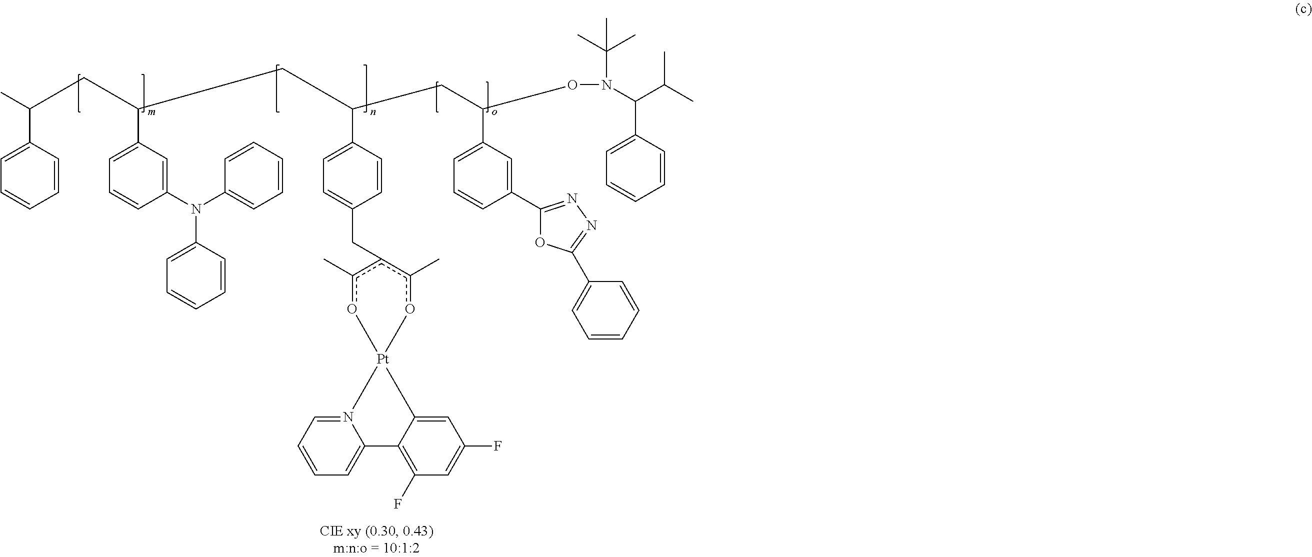

In addition, the light emitting layer 50 may be a mixture or blend of various polymers and low-molecular-weight materials. Therefore, it may make various colors such as blue, green, red, white, etc.

The thickness of the light emitting layer 50 may be about 50 Å to about 15000 Å, for example, about 200 Å to about 1000 Å. In the case where the thickness of the light emitting layer 50 satisfies the range as described above, high efficiency and excellent luminance can be achieved.

A hole injection layer 70 can be formed on top of the light emitting layer 50.

The hole injection layer 70 may contain a hole injecting material which is well-known in the art. For example, the hole injection layer 70 may contain one or more type of metal oxide and hole injecting organic materials.

In the case where the hole injection layer 70 contains a metal oxide, the metal oxide may include one or more type of metal oxide selected among MoO₃, WO₃ and V₂O₅. In the case where the hole injection layer consists of a metal oxide, the method for forming the hole injection layer follows the above-described method for forming the electron injection layer.

In the case the hole injection layer 70 contains a hole injecting organic material, the hole injection layer 70 can be formed according to a method optionally selected among various methods which are well-known in the art, such as, a vacuum deposition method, a spin coating method, a casting method, a Langmuir-Blodgett (LB) method, a spray coating method, a dip coating method, a gravure coating method, a reverse offset method, a screen printing method, a slot-die coating method and a nozzle printing method.

The above-described hole injecting organic material may include at least one selected from the group consisting of fullerene(C₆₀), HAT-CN, F₁₆CuP_{C}, CuP_{C}, m-MTDATA [4,4′,4″-tris(3-methylphenylphenylamino)triphenylamine], NPB (N,N′-di(1-naphthyl)-N,N′-diphenylbenzidine), TDATA, 2T-NATA, Pani/DB SA (Polyaniline/Dodecylbenzenesulfonic acid), PEDOT/PSS (Poly(3,4-ethylenedioxythiophene)/Poly(4-styrenesulfonate)), Pani/CSA (Polyaniline/Camphorsulfonicacid) and PANI/PSS ((Polyaniline)/Poly(4-styrenesulfonate)).

The chemical formulae of the materials above are as follows:

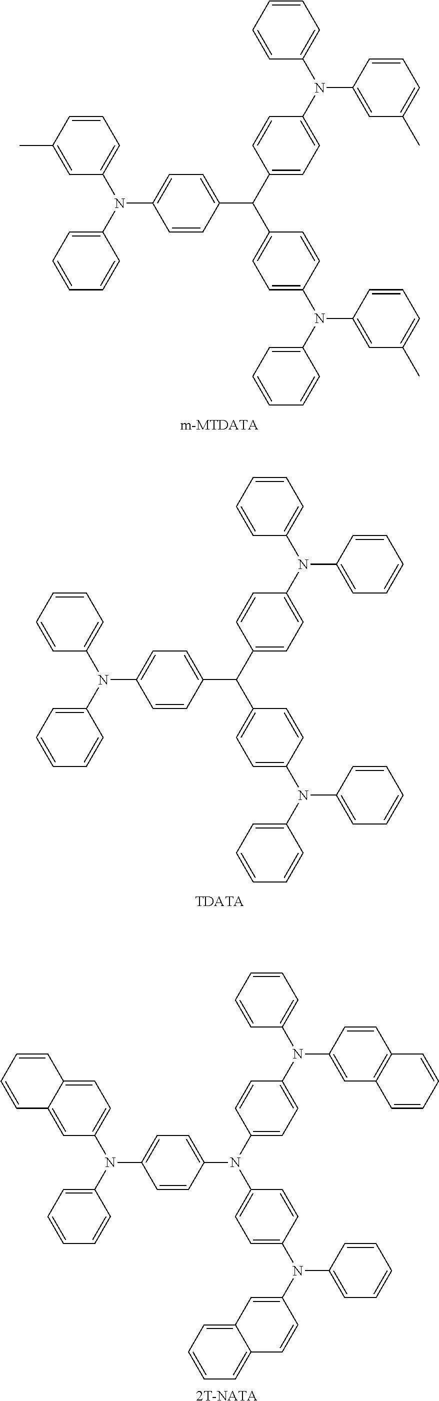

For example, the hole injection layer 70 may be a layer in which the above-described metal oxide is doped on a matrix of the above-described hole injecting organic material. In this case, it is preferable that the doping concentration is 0.1 wt % to 80 wt % based on total weight of the hole injection layer 70.

The thickness of the hole injection layer 70 may be 10 Å to 10000 Å, for example, 100 Å to 1000 Å. In the case where the thickness of the hole injection layer 70 satisfies the range as described above, driving voltage does not increase, and therefore, a high-quality organic device can be achieved.

In addition, a hole transporting layer 60 can be additionally formed between the light emitting layer 50 and the hole injection layer 70.

The hole transporting layer 60 can contain a hole transporting material well known in the art. For example, as for the hole transporting material which can be contained in the hole transporting layer 60, at least one selected from the group consisting of 1,3-bis(carbazol-9-yl)benzene (MCP), 1,3,5-tris(carbazol-9-yl)benzene (TCP), 4,4′,4″-tris(carbazol-9-yl)triphenylamine (TCTA), 4,4′-bis(carbazol-9-yl)biphenyl (CBP), N,N′-bis(naphthalen-1-yl)-N,N′-bis(phenyl)-benzidine (NPB), N,N′-bis(naphthalen-2-yl)-N,N′-bis(phenyl)-benzidine (β-NPB), N,N′-bis(naphthalen-1-yl)-N,N′-bis(phenyl)-2,2′-dimethylbenzidine (α-NPD), di-[4-(N,N-ditolyl-amino)-phenyl]cyclohexane (TAPC), N,N,N′,N′-tetra-naphthalen-2-yl-benzidine (β-TNB), and N4,N4,N4′,N4′-tetra(biphenyl-4-yl)biphenyl-4,4′-diamine (TPD15), poly(9,9-dioctylfluorene-co-bis-N,N′-(4-butylphenyl)-bis-N,N′-phenyl-1,4-phenylenediamine) (PFB), poly(9,9′-dioctylfluorene-co-N-(4-butylphenyl)diphenylamine) (TFB), poly(9,9′-dioctylfluorene-co-bis-N,N′-(4-butylphenyl)-bis-N,N′-phenylbenzidine) (BFB), poly(9,9-dioctylfluorene-co-bis-N,N′-(4-methoxyphenyl)-bis-N,N′-phenyl-1)(PFMO), and 4-phenylenediamine may be used, but it is not limited thereto.

The chemical formulae for the materials above are as follows:

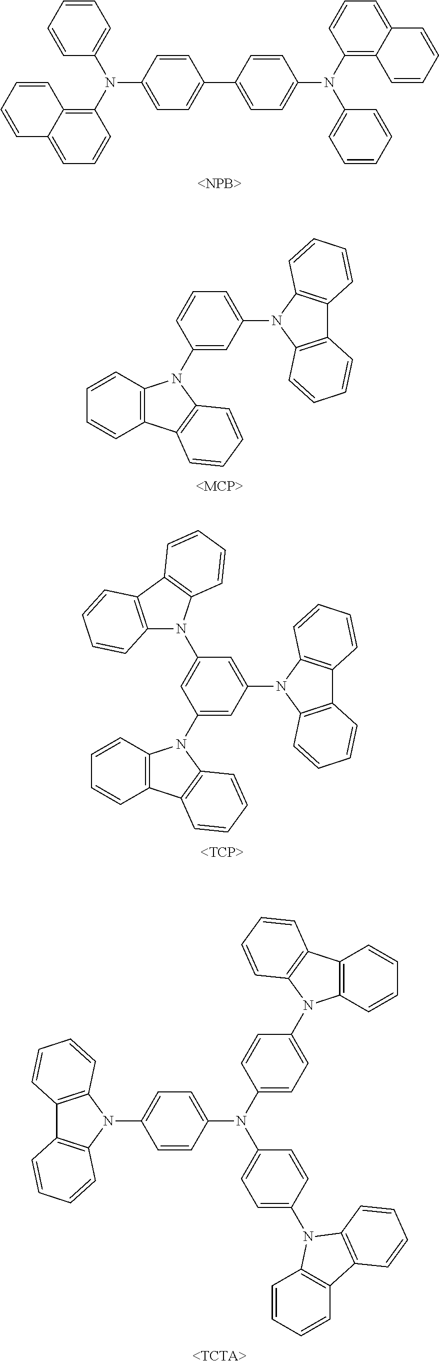 [SMILES: c1ccc(N(c2ccc(-c3ccc(N(c4ccccc4)c4cccc5ccccc45)cc3)cc2)c2cccc3ccccc23)cc1 ; c1cc(-n2c3ccccc3c3ccccc32)cc(-n2c3ccccc3c3ccccc32)c1 ; c1ccc2c(c1)c1ccccc1n2-c1cc(-n2c3ccccc3c3ccccc32)cc(-n2c3ccccc3c3ccccc32)c1 ; c1ccc2c(c1)c1ccccc1n2-c1ccc(N(c2ccc(-n3c4ccccc4c4ccccc43)cc2)c2ccc(-n3c4ccccc4c4ccccc43)cc2)cc1]

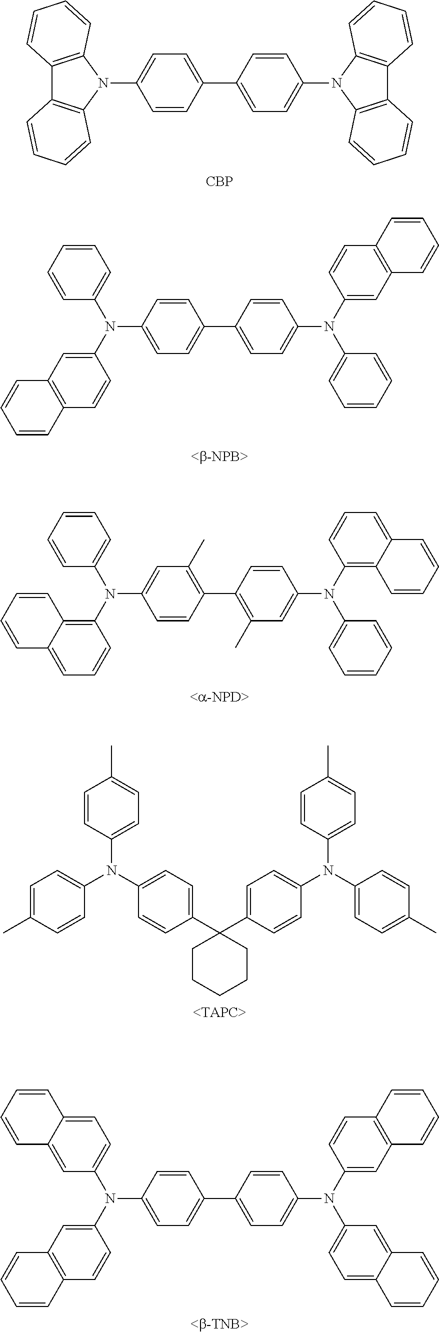

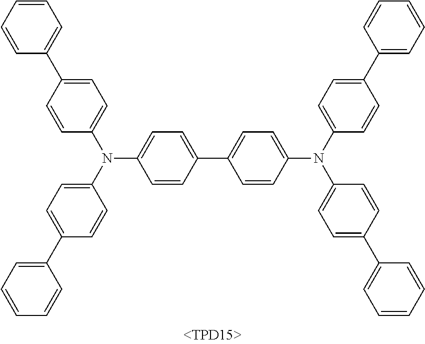 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1]

For example, in the case of TCTA among the hole transporting layer 60, in addition to transport of holes, it can serve to prevent excitons from diffusing away from the light emitting layer 50.

The thickness of the hole transporting layer 60 may be 5 nm to 100 nm, for example, 10 nm to 60 nm. In the case where the thickness of the hole transporting layer 60 satisfies the range as described above, the organic light emitting diode may have improved luminance efficiency and increased luminance.

The second electrode 80 can be formed on top of the hole injection layer 70.

The second electrode 80 as an anode may be a material having a relatively high work function. Specifically, for the second electrode layer 80, a metal, an alloy, an electric conductive compound and a combination thereof may be used. As a specific example, at least one among Ag, Al, Au, Mg, an alloy of Mg and Ag, an alloy of Mg and Al, an alloy of Mg and Au, an alloy of Ca and Al, an alloy of Li and Al, and a metal oxide (for example, MoO₃, WO₃ and V₂O₅) may be contained. The second electrode layer 80 may be formed by using a sputtering method, a vapor deposition method or an ion-beam deposition method.

On the other hand, any one or both of the hole injection layer 70 and the hole transporting layer 60 may be omitted.

Hereinafter, examples will be described for promoting an understanding of the present invention. However, the following examples should be considered in a descriptive sense only, and the scope of the invention is not limited by the following examples.

### Manufacturing Examples 1

An ITO electrode (cathode) was formed to a thickness of 180 nm on a 0.7 nm-thick glass substrate. Thereafter, each of the substrate and electrode was washed in acetone and isopropanol (IPA) for 20 minutes by using sonication. Thereafter, a ZnO electron injection layer was deposited to a thickness of 40 nm on the electrode by using sputtering. Thereafter, an electron injection interface layer was formed to a thickness of 4 nm on the electron injection layer by spin coating a mixture solution of 2-methoxyethanol and branched polyethyleneimine. Thereafter, a light emitting layer was formed to a thickness of 230 nm on the electron injection interface layer by spin coating solvent solution which dissolves the super yellow light emitting material (product name: PDY 132, (Merck Corp./Poly(para-phenylene vinylene) polymer derivative/0.9 wt %) in toluene and then heat-treating at 80° C. for 20 minutes. Thereafter, by forming an anode of MoO₃ (5 nm)/Ag (80 nm) through a deposition of MoO₃ (with a deposition rate of 0.3 Å/s) and Ag (with a deposition rate of 0.5 Å/s) one after another on the above-described light emitting layer, an organic light emitting device was produced (cathode (ITO): 180 nm, electron injection layer (ZnO): 40 nm, electron injection interface layer (PEI): 4 nm, light emitting layer (super yellow): 230 nm, anode (MoO₃/Ag): 5 nm/80 nm).

### Manufacturing Example 2

An organic light emitting device was manufactured through the same procedure as Manufacturing Example 1 except that the electron injection interface layer was deposited to a thickness of 8 nm (cathode (ITO): 180 nm, electron injection layer (ZnO): 40 nm, electron injection interface layer (PEI): 8 nm, light emitting layer (super yellow): 230 nm, anode (MoO₃/Ag): 5 nm/80 nm).

### Manufacturing Example 3

An organic light emitting device was manufactured through the same procedure as Manufacturing Example 1 except that the electron injection interface layer was deposited to a thickness of 12 nm (cathode (ITO): 180 nm, electron injection layer (ZnO): 40 nm, electron injection interface layer (PEI): 12 nm, light emitting layer (super yellow): 230 nm, anode (MoO₃/Ag): 5 nm/80 nm).

### Manufacturing Example 4

An organic light emitting device was manufactured through the same procedure as Manufacturing Example 1 except that the electron injection interface layer was deposited to a thickness of 16 nm (cathode (ITO): 180 nm, electron injection layer (ZnO): 40 nm, electron injection interface layer (PEI): 16 nm, light emitting layer (super yellow): 230 nm, anode (MoO₃/Ag): 5 nm/80 nm).

### Manufacturing Example 5

An organic light emitting device was manufactured through the same procedure as Manufacturing Example 1 except that a polyethylenimine ethoxylated (PEIE) was used instead of a branched polyethyleneimine for the formation of an electron injection interface layer (cathode (ITO): 180 nm, electron injection layer (ZnO): 40 nm, electron injection interface layer (PEIE): 4 nm, light emitting layer (super yellow): 230 nm, anode (MoO₃/Ag): 5 nm/80 nm).

### Manufacturing Example 6

An organic light emitting device was manufactured through the same procedure as Manufacturing Example 5 except that the electron injection interface layer was deposited to a thickness of 8 nm (cathode (ITO): 180 nm, electron injection layer (ZnO): 40 nm, electron injection interface layer (PEIE): 8 nm, light emitting layer (super yellow): 230 nm, anode (MoO₃/Ag): 5 nm/80 nm).

### Manufacturing Example 7

An organic light emitting device was manufactured through the same procedure as Manufacturing Example 5 except that the electron injection interface layer was deposited to a thickness of 12 nm (cathode (ITO): 180 nm, electron injection layer (ZnO): 40 nm, electron injection interface layer (PEIE): 12 nm, light emitting layer (super yellow): 230 nm, anode (MoO₃/Ag): 5 nm/80 nm).

### Manufacturing Example 8

An organic light emitting device was manufactured through the same procedure as Manufacturing Example 5 except that the electron injection interface layer was deposited to a thickness of 16 nm, an organic light emitting device was manufactured through the same procedure as Manufacturing Example 5 (cathode (ITO): 180 nm, electron injection layer (ZnO): 40 nm, electron injection interface layer (PEIE): 16 nm, light emitting layer (super yellow): 230 nm, anode (MoO₃/Ag): 5 nm/80 nm).

### Comparative Example

An organic light emitting device was manufactured through the same procedure as Manufacturing Example 1 except that the light emitting layer was formed directly on the electron injection layer without the formation of an electron injection interface layer (cathode (ITO): 180 nm, electron injection layer (ZnO): 40 nm, light emitting layer (super yellow): 230 nm, anode (MoO₃/Ag): 5 nm/80 nm).

Table 1 is a table which shows the work functions of electron injection layer/electron injection interface layers during the manufacture of an organic light emitting device according to Manufacturing Example 1 to Manufacturing Example 8 and Comparative Example.

TABLE 1

| | Electron injection | Thickness of | |
|---|---|---|---|
| | layer/electron | electron | |
| | injection | injection | Work |
| | interface layer | interface layer | function |
| Comparative Example | ZnO | 0 nm | 4.4 eV |
| Manufacturing Example 1 | ZnO/PEI | 4 nm | 2.47 eV |
| Manufacturing Example 2 | ZnO/PEI | 8 nm | 2.44 eV |
| Manufacturing Example 3 | ZnO/PEI | 12 nm | 3.17 eV |
| Manufacturing Example 4 | ZnO/PEI | 16 nm | 3.39 eV |
| Manufacturing Example 5 | ZnO/PEIE | 4 nm | 3.29 eV |
| Manufacturing Example 6 | ZnO/PEIE | 8 nm | 3.36 eV |
| Manufacturing Example 7 | ZnO/PEIE | 12 nm | 3.55 eV |
| Manufacturing Example 8 | ZnO/PEIE | 16 nm | 3.6 eV |

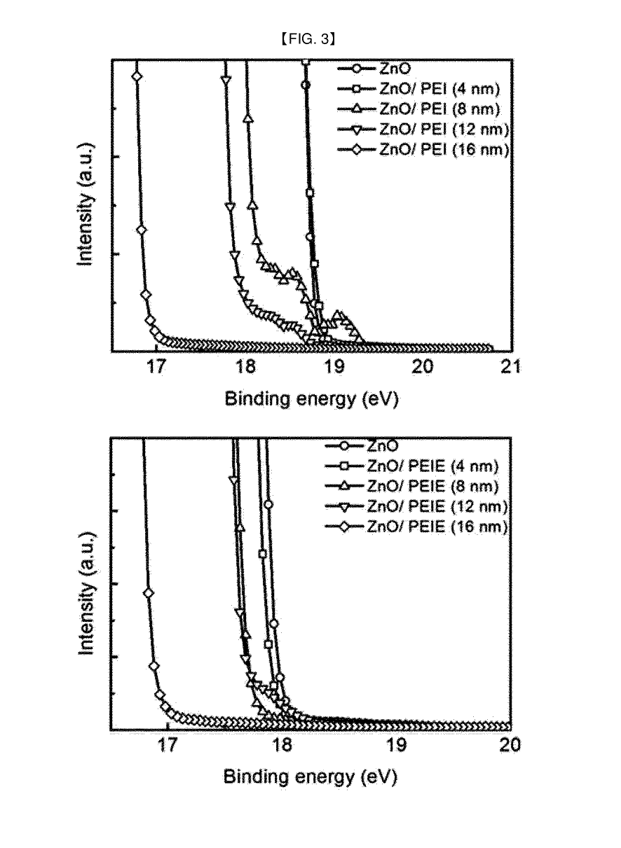

FIG. 3 is graphs showing changes in the work functions of the electron injection layers prepared according to Manufacturing Examples 1 to 8 and Comparative Example.

Referring to Table 1 and FIG. 3, it can be seen that the work function of an electron injection layer decreases when an electron injection interface layer is formed. In addition, in the case where PEI is used for the electron injection interface layer, the work function is lower compared to the case where PEIE is used. On the other hand, as the thickness of the electron injection interface layer increases, the work function gradually increases. However, it can be seen that, even when the thickness of the electron injection interface layer is 16 nm, the work function is lower than that of the electron injection layer (ZnO) itself.

As a result, by forming a polymer which contains a nitrogen atom into an electron injection interface layer on the electron injection layer, it is possible to reduce the work function below that of the electron injection layer itself, thereby facilitating injection of electrons into the light emitting layer. In addition, it is possible to control injection of electrons into the light emitting layer by controlling the work function of the electron injection layer through the thickness of the electron injection interface layer. As a result, the luminance efficiency of an organic light emitting device can be improved.

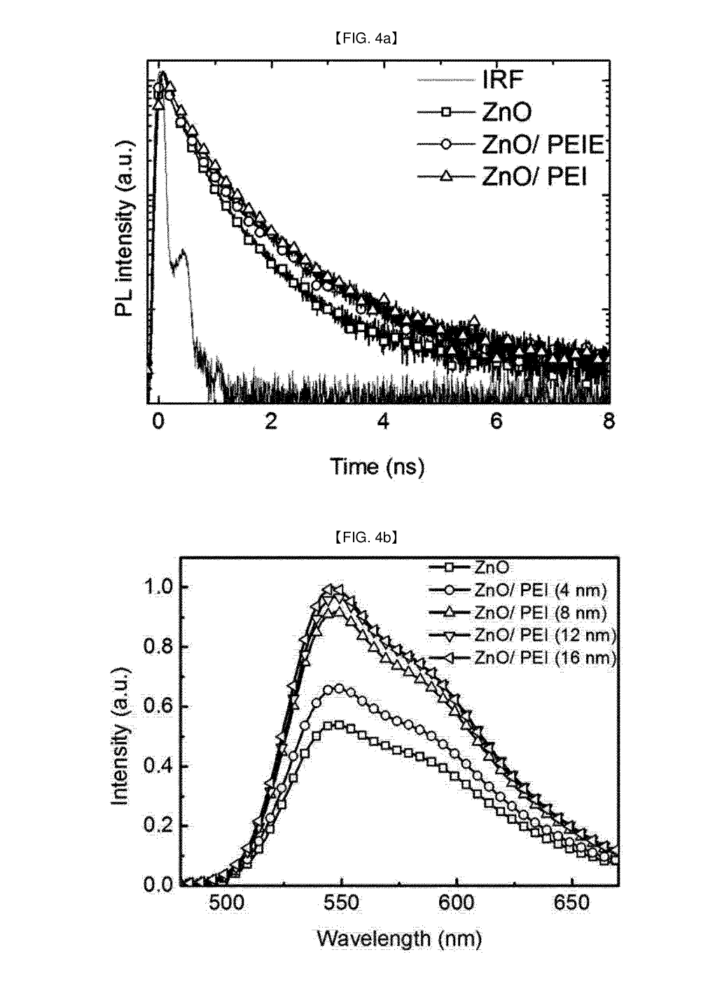

FIG. 4a is a graph showing the measured lifetime of excitons when a light emitting layer is deposited during the manufacture of organic light emitting devices according to Manufacturing Example 2, Manufacturing Example 6 and Comparative Example (measurement of lifetime with light emitting layer thickness at 10 nm, incident light: 420 nm, 550 nm).

Referring to FIG. 4a, it can be seen that dissociation of excitons, which may be caused due to the electron injection layer (ZnO), is prevented in the case where PEI (8 nm) or PEW (8 nm) is used for the electron injection interface layer 33, leading to an increase in the lifetime of excitons, and therefore, the efficiency of a device is improved.

FIG. 4b is a photoluminescence graph showing the measured intensity of excitons when a light emitting layer is deposited according to Manufacturing Example 1, Manufacturing Example 2, Manufacturing Example 3, Manufacturing Example 4 and Comparative Example (light emitting layer thickness at 10 nm, incident light: 450 nm).

Referring to FIG. 4b, it can be seen that the distance between an exciton which is formed in a light emitting layer and the electron injection layer 31 causing exciton dissociation decreases as the thickness of an electron injection interface layer increases, and therefore, the photoluminescence intensity increases.

Table 2 is a table showing the maximum efficiency of organic light emitting devices obtained by Manufacturing Example 1, Manufacturing Example 2, Manufacturing Example 3, Manufacturing Example 4, Manufacturing Example 6 and Comparative Example (for luminance efficiency measurement, Keithely 236 source measure unit and Minolta CS2000 spectroradiometer were used).

TABLE 2

| | | Thickness | |
|---|---|---|---|
| | Electron injection | of electron | |
| | layer/electron | injection | |
| | injection interface | interface | Maximum |
| | layer | layer | efficiency |
| Comparative Example | ZnO | 0 nm | 0.08 cd/A |
| Manufacturing Example 1 | ZnO/PEI | 4 nm | 8.5 cd/A |
| Manufacturing Example 2 | | 8 nm | 13.5 cd/A |
| Manufacturing Example 3 | | 12 nm | 13.1 cd/A |
| Manufacturing Example 4 | | 16 nm | 5.04 cd/A |
| Manufacturing Example 6 | ZnO/PEIE | 8 nm | 12 cd/A |

Referring to Table 2, the organic light emitting device according to Manufacturing Examples (particularly Manufacturing Example 2) showed a maximum efficiency of about 13.5 cd/A, and the value is significantly higher compared to the maximum efficiency of the organic light emitting device according to Comparative Example at about 0.08 cd/A. On the other hand, it can be seen that the maximum efficiency is improved when the thickness of the electron injection interface layer is 8 nm to 12 nm, compared to other cases.

Hereupon, the present invention was described in detail with reference to embodiments, but the present invention is not limited by the above-described embodiments, and various modifications and changes by those skilled in the art within the spirit and scope of the present invention are possible.

1. An inverse-structure organic light emitting diode comprising:
a first electrode;
an electron injection layer which includes a metal oxide and is disposed on the first electrode;
a electron injection interface layer, which includes a polymer including a nitrogen atom, on the electron injection layer;
a light emitting layer disposed on the electron injection interface layer; and
a second electrode disposed on the light emitting layer.

2. The inverse-structure organic light emitting diode of claim 1, wherein the polymer is a dielectric polymer.

3. The inverse-structure organic light emitting diode of claim 1, wherein the polymer includes an amine group, an azo group or an ammonium group in a main or side chain thereof.

4. The inverse-structure organic light emitting diode of claim 3, wherein the polymer is a polyethylenimine-based polymer or a polyallylamine-based polymer.

5. The inverse-structure organic light emitting diode of claim 3, wherein the polymer includes at least one selected from the group consisting of branched polyethyleneimine, polyethyleneimine ethoxylated, poly(2-ethyl-2-oxazoline), linear polyethyleneimine, bioreducible disulfide-crosslinked polyethyleneimine, polyethyleneimine max, polyallylamine, polyallylamine hydrochloride, poly(1-(4-(3-carboxy-4hydroxyphenylazo)benzenesulfonamido)-1,2-ethanediyl, sodium salt) and poly(diallyldimethylammonium chloride).

6. The inverse-structure organic light emitting diode of claim 1, wherein the electron injection interface layer has a thickness of 1 nm to 20 nm.

7. The inverse-structure organic light emitting diode of claim 6, wherein the electron injection interface layer has a thickness of 4 nm to 16 nm.

8. The inverse-structure organic light emitting diode of claim 7, wherein the electron injection interface layer has a thickness of 8 nm to 12 nm.

9. The inverse-structure organic light emitting diode of claim 1, wherein the electron injection layer is a thin film layer of a metal oxide, a layer of metal-oxide nanoparticles, or a layer in which metal-oxide nanoparticles are included in a metal-oxide thin film.

10. The inverse-structure organic light emitting diode of claim 1, wherein the metal oxide is an n-type semiconducting metal oxide.

11. The inverse-structure organic light emitting diode of claim 10, wherein the metal oxide is one or more type selected from the group consisting of TiOₓ (where x is a real number of 1 to 3), indium oxide (In₂O₃), tin oxide (SnO₂), zinc oxide (ZnO), zinc tin oxide, gallium oxide (Ga₂O₃), tungsten oxide (WO₃), aluminum oxide, titanium oxide, vanadium oxide, molybdenum oxide, copper(II) oxide (CuO), nickel oxide (NiO), CopperAluminumOxide (CAO, CuAlO₂), ZincRhodiumOxide (ZRO, ZnRh₂O₄), iron oxide, chromium oxide, bismuth oxide, IGZO (indium-Gallium Zinc Oxide) and ZrO₂.

12. The inverse-structure organic light emitting diode of claim 1, wherein a hole injection layer including a metal oxide is disposed between the second electrode and the light emitting layer.

13. An inverse-structure organic light emitting diode comprising:
a first electrode;
an electron injection layer which includes a metal oxide and is disposed on the first electrode;
a electron injection interface layer, which includes a polymer capable of forming an interface dipole by bonding with oxygen of the metal oxide, on the electron injection layer;
a light emitting layer disposed on the electron injection interface layer; and
a second electrode disposed on the light emitting layer.

14. A method of manufacturing an inverse-structure organic light emitting diode, the method comprising:
forming a first electrode;
forming an electron injection layer which includes a metal oxide on the first electrode;
forming a electron injection interface layer which includes a polymer including a nitrogen atom on the electron injection layer;
forming a light emitting layer on the electron injection interface layer; and
forming a second electrode on the light emitting layer.

15. The method of claim 14, wherein the electron injection interface layer is formed by applying a liquid mixture, which includes the polymer and a polar solvent, on the electron injection layer.

16. The method of claim 14, wherein the polymer is a dielectric polymer.

17. The method of claim 14, wherein the polymer includes an amine group, an azo group or an ammonium group in a main or side chain thereof.

18. The method of claim 17, wherein the polymer is a polyethylenimine-based polymer or a polyallylamine-based polymer.

19. The method of claim 17, wherein the polymer includes at least one selected from the group consisting of branched polyethyleneimine, polyethyleneimine ethoxylated, poly(2-ethyl-2-oxazoline), linear polyethyleneimine, bioreducible disulfide-crosslinked polyethyleneimine, polyethyleneimine max, polyallylamine, polyallylamine hydrochloride, poly(1-(4-(3-carboxy-4hydroxyphenylazo)benzenesulfonamido)-1,2-ethanediyl, sodium salt) and poly(diallyldimethylammonium chloride).

20. The method of claim 14, wherein the electron injection interface layer has a thickness of 1 nm to 20 nm.

21. The method of claim 14, wherein the electron injection layer is a layer which is a thin film layer of a metal oxide, a layer of metal-oxide nanoparticles, or a layer in which metal-oxide nanoparticles are included in a metal-oxide thin film.

22. The method of claim 14, wherein the metal oxide is an n-type semiconducting metal oxide.

23. The method of claim 14, wherein the electron injection interface layer is formed using a sol-gel method or a deposition method.
